(19) United States
(12) Patent Application Publication
(10) Pub. No.: US 2026/0349353 A1
(43) Pub. Date: Nov. 5, 2026

(54) MACHINE LEARNING-BASED RAPID OPTICAL METROLOGY SYSTEM AND METHOD

(71) Applicant: BOARD OF REGENTS, THE UNIVERSITY OF TEXAS SYSTEM, Austin, TX (US)

(72) Inventors: Draga DJURDJANOVIC, Austin, TX (US); Ramin SABBAGH, Austin, TX (US)

(21) Appl. No.: 19/488,994

(22) PCT Filed: May 31, 2024
(86) PCT No.: PCT/US2024/032117

§ 371 Date: Dec. 1, 2025

Related U.S. Application Data
(60) Provisional application No. 63/505,635, filed on Jun. 1, 2023.
(60) Provisional application No. 63/584,969, filed on Sep. 25, 2023.

(51) Int. Cl. G03F 7/00

(52) U.S. Cl. CPC G03F 7/7065; G03F 7/706841

(57) ABSTRACT

An exemplary scatterometry-based metrology system and method are disclosed that can perform high-throughput inspection, using AI classifier, of geometric characteristics of large-area micro or nanopatterned surfaces in a fabricated or partially fabricated devices to identify an anomaly in a fabricated workpiece, its batch, or its associated processing or equipment. The exemplary metrology system and method utilize physics-based dependencies between reflectance of light scattered from micro or nanopatterned surfaces for a pre-defined set of wavelengths and the geometric characteristics of the nanopatterns to train an AI classifier for a device design using variations in critical dimensions of that device design. The trained AI classifier can then be used to predict/estimate critical dimensions of critical dimensions of a fabricated or partially fabricated device.

### RELATED APPLICATION

This PCT patent application claims priority to, and the benefit of, U.S. Provisional Patent Application No. 63/584,969, filed Sep. 25, 2023, entitled “MACHINE LEARNING-BASED RAPID OPTICAL METROLOGY SYSTEM AND METHOD,” and U.S. Provisional Patent Application No. 63/505,635, filed Jun. 1, 2023, entitled “MACHINE LEARNING-BASED RAPID OPTICAL METROLOGY SYSTEM AND METHOD,” each of which is incorporated by reference herein in its entirety.

### BACKGROUND

Nanophotonic structures are finding applications in high-speed lossless communications, diffractive optics, photonic crystals, negative index-of-refraction materials, flat lenses, perfect reflectors, perfect absorbers, and cloaking devices. Modern high-throughput nanopatterning techniques, such as nanoimprint lithography, enable fabrication of Large-area Nanostructure Arrays (LNAs) on wafers and roll-to-roll substrates reaching scales as large as cm² or m². The capability of manufacturing such LNAs on a variety of substrates has enabled the design and manufacturing of a wide array of products, including optical devices, such as wire-grid polarizers, transparent conductors, color filters, and anti-reflection surfaces, as well as building blocks for electronic components, such as ultra-capacitors, optical sensors, and memory storage architectures, and many other applications.

While manufacturing can be scaled to high volume production of LNA deviecs and components, as well as microelectronics and microelectromechanical (MEMs) devices, metrology and quality assessments of such manufactured devices and components remain for the most part untouched. Nano-scale metrology techniques such as scanning electron microscopy (SEM) or atomic force microscopy (AFM) can be employed to measure critical dimensions of nanofeatures but for only specific locations on the device, limited to its field of view and requires the workpiece to be sacrificed.

There is a need and benefit to improve the metrology of electronic and microelectromechanical devices and components.

### SUMMARY

An exemplary scatterometry-based metrology system and method are disclosed that can perform high-throughput inspection, using AI model (e.g., AI classifier), of geometric characteristics of large-area micro or nanopatterned surfaces in a fabricated or partially fabricated devices to identify an anomaly in a fabricated workpiece, its batch, or its associated processing or equipment. The exemplary metrology system and method utilize physics-based dependencies between reflectance of light scattered from micro or nanopatterned surfaces for a pre-defined set of wavelengths and the geometric characteristics (also referred to herein as Critical Dimensions (CDs)) of the nanopatterns to train an AI model for a device design using variations in critical dimensions of that device design. The trained AI model can then be used to predict/estimate critical dimensions of critical dimensions of a fabricated or partially fabricated device.

Notably, the exemplary system and method can achieve inspection and provide CD inference of a full wafer with complex micro or nano structures within minutes. The exemplary system and method can be employed for full in-process inspection of every wafer, which, in turn can lead to greatly improved process and quality control.

A study was conducted that a trained AI model can be sufficiently trained to evaluate fabricated or partially fabricated devices having critical dimensions as the training set or having a variant of such critical dimensions. Because the trained AI model can evaluate variants of a device design for variant critical dimensions, only a partial set of the device design is needed for the training, which was observed to significantly improve the setup time for the evaluation of a given device over conventional matching evaluation that requires priori generated reference library of reflectance spectra to be simulated for an exhaustive set of possible underlying CDs characterizing the measured nanopatterns. Generating a training library via the exemplary method, with a resolution sufficiently high to result in adequate accuracy of the predicted CDs is time efficient and feasible even for complex micro nanopatterns.

In addition, the trained AI model, during runtime operation, can operate in real-time or near real-time, as well as off-time analysis, to provide accurate and repeatable metrology of CDs of complex micro or nanopatterns for surfaces of a fabricated or partially fabricated semiconductor workpiece or other micro or nano devices described herein. The exemplary system and method can provide one or more critical dimension values (e.g., the structure can have between 1 and 50 CD values) associated with a periodic structure in an area of the semiconductor wafer or microelectromechanical device having multiple periodic structures. The exemplary system and method can operate with spot measurement that includes an area of the semiconductor wafer or microelectromechanical device having multiple of the periodic structure or an array sensor to which multiple spots corresponding to multiple areas of the semiconductor wafer or microelectromechanical device can be simultaneously evaluated. In the later example, the sensor array can represent each measured spot as a pixel is a set of pixels for a large-scale measurement of the semiconductor wafer or microelectromechanical device.

While micro or nanopatterned structures are generally characterized by a set of critical dimension values, e.g., 1-15, it is contemplated that the exemplary system and method can provide increased resolution evaluation of the structure, e.g., extending the same 1-15 CD to 15-50 CDs in which angled surfaces and profiles of surfaces can be evaluated for anomalies.

The exemplary system and method can provide rapid and accurate inference of underlying critical dimensions of a device design from reflectance spectra. In some embodiments, the training system is configured to solve a machine learning (ML) based inverse problem that optimizes the down-selection of spectral wavelengths involved in the inspection process. In some embodiments, Latin Hypercube Sampling is utilized to create a set of CD vectors, which are used as inputs for physics-based simulations of reflectance spectra expected from the corresponding nanopatterned surface.

In an aspect, a method is disclosed for optical inspection of a processed semiconductor wafer (final processed or in-process) or microelectromechanical device comprising: obtaining or receiving a measured reflectance spectra profile (e.g., multi-spectral data set or images, e.g., for a spot or an array) for one or more processed semiconductor wafer or microelectromechanical devices (e.g., a batch thereof) acquired by a metrology equipment, including a processed semiconductor wafer or microelectromechanical device; determining, via an analysis operation using one or more trained machine learning models, using the measured reflectance spectra profile, one or more critical dimension values (e.g., structure can have between 1 and 50 CD values) associated with a periodic structure in at least one area, including a first area, of the processed semiconductor wafer or microelectromechanical device, wherein the one or more critical dimension values is determined by providing the measured reflectance spectra profile to the one or more trained machine learning models (e.g., XG-Boost or other ML algorithms), wherein the machine learning model was trained from a set of simulation outputs, as a training data set, of a physic-based simulation model (e.g., from a simulation software), wherein the set of simulation outputs comprises (i) the periodic structure in the at least one area of the processed semiconductor wafer or microelectromechanical device configured with a first set of one or more critical dimension values, (ii) the periodic structure in the at least one area of the processed semiconductor wafer or microelectromechanical device configured with a second set of one or more critical dimension values, and (iii) simulated reflectance spectra profiles for the periodic structures configured with the first set of one or more critical dimension values and the second set of one or more critical dimension values; and outputting the determined one or more critical dimension values for the processed semiconductor wafer or microelectromechanical device (e.g., in a report or in a control command), wherein the outputted one or more critical dimensional values, or a parameter derived therefrom, are used to accept or reject (i) the processed semiconductor wafer or microelectromechanical device, (ii) a batch associated with the processed semiconductor wafer or microelectromechanical device, or (iii) equipment or process employed in the fabrication of the processed semiconductor wafer or microelectromechanical device.

In some embodiments, the outputted one or more critical dimensional values, or a parameter derived therefrom, is used to accept or reject the processed wafer or the processed semiconductor wafer or microelectromechanical device and in real-time or off-line analysis.

In some embodiments, the periodic structure in the area of the processed semiconductor wafer or microelectromechanical device includes at least one of: a repeating metal grating structure, a repeating metal grid structure, a repeating nanopillar structure, a repeating nanowire structure, vertical pillar transistor structure, a repeating planer structure, a repeating FinFET structure, and repeating gate-all-around (GAA) structure, or a Large-area Nanostructure Array (LNA).

In some embodiments, the outputted one or more critical dimensional values, or a parameter derived therefrom, is used to trigger (i) a second measurement and analysis via the trained machine learning models or (ii) a manual inspection of the processed semiconductor wafer or microelectromechanical device.

In some embodiments, the method further includes determining, via the trained machine learning models, a second set of one or more critical dimension values associated with a periodic structure in a second area of the processed semiconductor wafer or microelectromechanical device, wherein the determined second set of one or more critical dimension values, or a parameter derived therefrom, is used to accept or reject (i) the processed semiconductor wafer or microelectromechanical device, (ii) the batch associated with the processed semiconductor wafer or microelectromechanical device, or (iii) the equipment or process employed in the fabrication of the processed semiconductor wafer or microelectromechanical device.

In some embodiments (e.g., for an analysis system implemented in a metrology system), the method further comprising: measuring the processed semiconductor wafer or microelectromechanical device to acquire the measured reflectance spectra profile; and storing (i) the measured reflectance spectra profile and (ii) associated location or periodic structure of the processed semiconductor wafer or microelectromechanical device to provide for the analysis operation.

In some embodiments, the one or more processed semiconductor wafer or microelectromechanical devices (e.g., a batch thereof) include a second processed semiconductor wafer or microelectromechanical device, the method includes determining, via the one or more trained machine learning models, a third set of one or more critical dimension values associated with a periodic structure in an area of the second processed semiconductor wafer or microelectromechanical device, wherein the determined third set of one or more critical dimension values, or a parameter derived therefrom, is used to accept or reject (i) the second processed semiconductor wafer or microelectromechanical device, (ii) the batch associated with the processed semiconductor wafer or microelectromechanical device, or (iii) the equipment or process employed in the fabrication of the processed semiconductor wafer or microelectromechanical device.

In some embodiments, the method further includes estimating, via a second trained machine learning model, using the measured reflectance spectra profile, the periodic structure in the area of the processed semiconductor wafer or microelectromechanical device, and the estimated periodic structure is used to select the one or more trained machine learning models for the analysis operation.

In some embodiments, the measured reflectance spectra profile is measured by a scatterometry-based metrology system (ellipsometric scatterometry equipment, angular scatterometry equipment, etc.) as the metrology equipment.

In some embodiments, the measured reflectance spectra profile corresponds to a measurement for a single location on a single processed semiconductor wafer or microelectromechanical device.

In some embodiments, the measured reflectance spectra profile corresponds to a measurement for multiple locations on a single processed semiconductor wafer or microelectromechanical device from a metrology equipment having an arrayed sensor.

In some embodiments, the measured reflectance spectra profile is represented as an image having a plurality of pixels, wherein each pixel corresponds to an area of the processed semiconductor wafer or microelectromechanical device having a plurality of periodic structures.

In some embodiments, the analysis operation is performed in a batch.

In some embodiments, measurement by the metrology equipment is performed in a batch.

In some embodiments, the processed semiconductor wafer or microelectromechanical device has an area greater than 300 mm² (e.g., up to 1 m²).

In some embodiments, the area of the processed semiconductor wafer or microelectromechanical device has an area greater than 1 mm².

In some embodiments, the trained machine learning models include XG-Boost.

In some embodiments, the simulation tool includes a photonic multiphysics simulation tool (e.g., Ansys Lumerical) (e.g., finite difference time domain (FDTD), rigorous coupled wave analysis, etc.).

In some embodiments, the processed semiconductor wafer or microelectromechanical device is a silicon wafer, a glass sheet, or a flexible roll-to-roll web, having a micropatterned or nanopatterned periodic structure.

In some embodiments, the outputted one or more critical dimensional values, or a parameter derived therefrom, has a comparable Gage R&R ratio to manual inspection operation via Scanning Electron Microscopy or Atomic Force Microscopy (AFM)-based metrology.

In some embodiments, the processed semiconductor wafer or microelectromechanical device is configured as a dynamic random access memory (DRAM) core circuit, a static random access memory (SRAM) core circuit, a magnetoresistive random-access memory (MRAM) core circuit.

In some embodiments, the processed semiconductor wafer or microelectromechanical device is configured as a photovoltaic device or cell.

In some embodiments, the processed semiconductor wafer or microelectromechanical device is configured as a photovoltaic device or cell.

In some embodiments, the processed semiconductor wafer or microelectromechanical device is configured as a microstructure devices (e.g., photonic waveguides and filters, e.g., in flexible electronics), liquid crystal display (LCD), organic light emitting diode (OLED) display, or capacitive touch screen sensor.

In some embodiments, the periodic structure in at least one area of the processed semiconductor wafer or microelectromechanical device is different from the first and second set of one or more critical dimension values, and wherein the analysis operation is not a matching operation.

In another aspect, a method is disclosed for training a machine learning comprising: generating, via a physic-based simulation model (e.g., from a simulation software), a library of a plurality of simulation reflectance spectra profiles for a set of periodic structures in a semiconductor wafer or microelectromechanical device having an associated set of one or more critical dimension values, wherein the generated library of the plurality of simulation reflectance spectra profiles and associated set of one or more critical dimension values are used to train a machine learning model, and wherein the trained machine learning model is subsequently used to determine one or more critical dimension values, or parameters derived therefrom, of a periodic structure in at least one area of the fabricated semiconductor wafer or microelectromechanical device from measured reflectance spectra profile acquired by a metrology equipment, wherein the determined one or more critical dimensional values, or the parameter derived therefrom, are used to accept or reject (i) the fabricated semiconductor wafer or microelectromechanical device, (ii) a batch associated with the fabricated semiconductor wafer or microelectromechanical device, or (iii) equipment or process employed in the fabrication of the fabricated semiconductor wafer or microelectromechanical device.

In some embodiments, the method further includes training the machine learning model using the plurality of simulation reflectance spectra profiles and the associated set of one or more critical dimension values.

In some embodiments, the library is generated using Latin Hypercube Sampling (or others).

In some embodiments, the method further includes down-selecting a set of one or more critical dimension values for the library of the plurality of simulation reflectance spectra profiles to be used for the training.

In another aspect, a scatterometry-based metrology system is disclosed comprising: a test platform coupled to a laser source; laser control system configured to perform scatterometry-based metrology on a work product in the test platform; and an analysis system configured to perform optical inspection of critical dimensions of a processed wafer or work product using any one of the above-discussed methods.

In another aspect, an analysis system is disclosed for scatterometry-based metrology comprising: a processor; and a memory having instructions stored thereon, wherein execution of the instructions by the processor causes the processor to perform optical inspection of critical dimensions of a processed semiconductor wafer or microelectromechanical device according to any one of the above-discussed methods.

In another aspect, a non-transitory computer-readable medium is disclosed having instructions stored thereon, wherein execution of the instructions by a processor causes the processor to perform optical inspection of critical dimensions of a processed semiconductor wafer or microelectromechanical device according to any one of the above-discussed methods.

Other systems, methods, features and/or advantages will be or may become apparent to one with skill in the art upon examination of the following drawings and detailed description. It is intended that all such additional systems, methods, features and/or advantages be included within this description and be protected by the accompanying claims.

### BRIEF DESCRIPTION OF DRAWINGS

The components in the drawings are not necessarily to scale relative to each other. Like reference, numerals designate corresponding parts throughout the several views.

FIGS. 1A, 1B, and 1C each shows an example scatterometry-based metrology system for optical inspection of a processed semiconductor wafer or microelectromechanical device in accordance with an illustrative embodiment.

FIG. 2A shows an example method of performing metrology measurement and prediction/estimation of critical dimensions for an exemplary fabricated device or workpiece in accordance with an illustrative embodiment.

FIG. 3 shows an example method of training the exemplary AI model, e.g., described in relation to FIGS. 1A, 1B, and 1C in accordance with an illustrative embodiment.

FIGS. 4A and 4B show the use of an exemplary system for the optical inspection of a processed semiconductor wafer (final processed or in-process) or microelectromechanical device.

FIGS. 5A-5D show a setup of a study conducted to develop an AI scatterometry-based metrology system and method.

FIG. 5E-5G show performance results of the AI scatterometry-based metrology system and method of FIG. 5A-5D.

FIG. 5H-5K shows Gage R&R evaluation that was performed on a complex semiconductor device using simulated scatterometry-based metrology system and method. The Gage R&R evaluation results show the exemplary system and method to be repeatable and reproducable.

FIGS. 6A-6I show example fabrication operations and fabricated structures to which the exemplary scatterometry-based metrology system can be employed to evaluate.

### DETAILED DESCRIPTION

It is appreciated that certain features of the disclosure, which are, for clarity, described in the context of separate aspects, can also be provided in combination with a single aspect. Conversely, various features of the disclosure, which are, for brevity, described in the context of a single aspect, can also be provided separately or in any suitable subcombination. Unless defined otherwise, all technical and scientific terms used herein have the same meaning as commonly understood by one of ordinary skill in the art. Methods and materials similar or equivalent to those described herein can be used in the practice or testing of the present disclosure.

### Example System

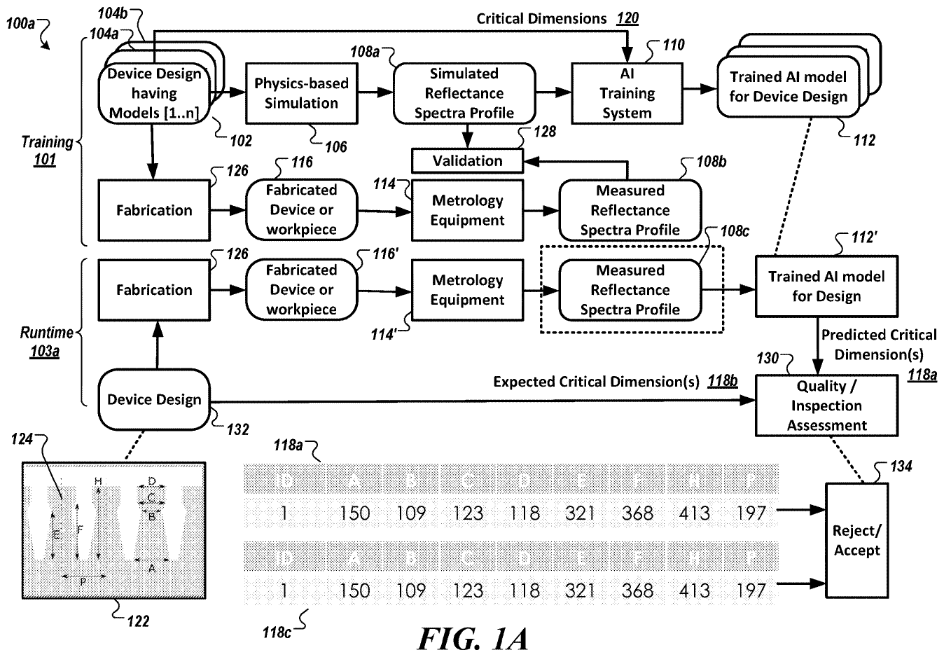

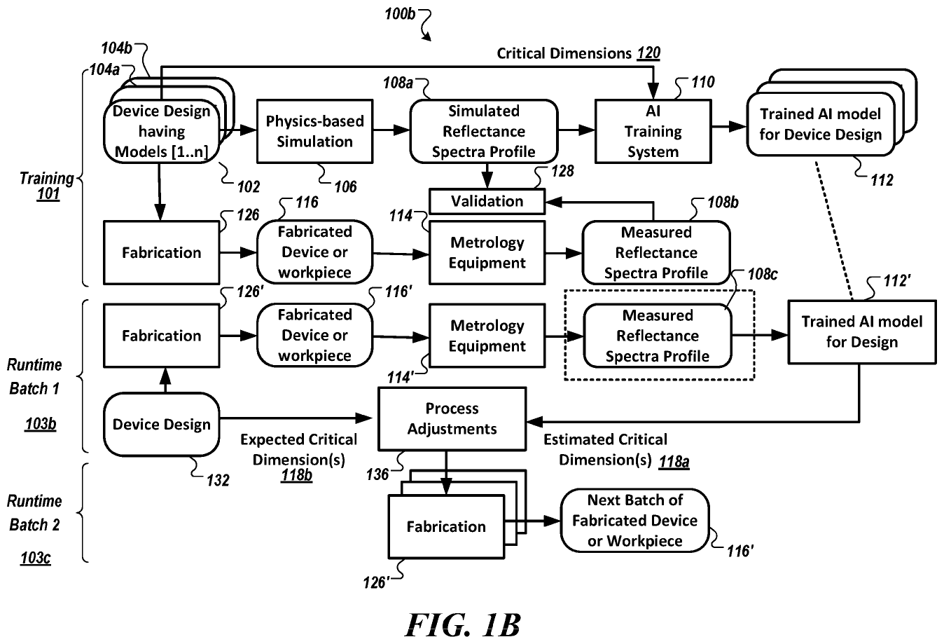

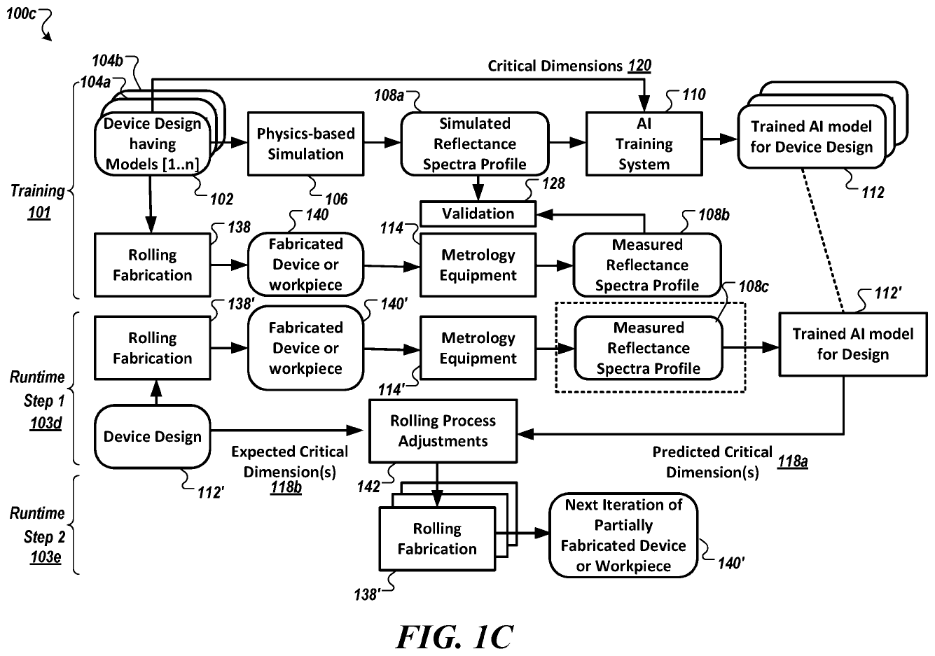

FIGS. 1A, 1B, and 1C show an example scatterometry-based metrology system 100 (shown as 100a, 100b, 100c) for optical inspection of a processed semiconductor wafer (final processed or in-process) or microelectromechanical device. The exemplary system 100 utilizes physics-based dependencies between the reflectance of light scattered from micro or nanopatterned surfaces for a pre-defined set of wavelengths and the geometric characteristics (also referred to herein as Critical Dimensions (CDs)) of the nanopatterns to train an AI model (e.g., AI classifier) for a device design using variations in critical dimensions of that device design. The trained AI model is then used to predict/estimate critical dimensions of critical dimensions of a fabricated or partially fabricated device.

As used herein, the term “semiconductor wafer” refers to a thin device made of a semiconductive material (e.g., silicon) having an array of periodic microstructures or nanostructures, often periodic, that implement an electrical or microelectromechanical (MEM) circuit. The microstructures or nanostructures create a relationship between voltage and current necessary to perform a variety of electrical functions. A “processed semiconductor wafer” refers to a semiconductor wafer that has undergone, in full or in part, the manufacturing process of forming the microstructures or nanostructures and has an array of periodic microstructures or nanostructures. As used herein, the term “microelectromechanical device” refers to a device with micron-scale features fabricated therein that incorporate both electronic and mechanical elements. Periodic structures of interest in the processed semiconductor wafer or microelectromechanical device may include, but are not limited to, a repeating metal grating structure, a repeating metal grid structure, a repeating nanopillar structure, a repeating nanowire structure, vertical pillar transistor structure, a repeating planer structure, a repeating FinFET structure, and repeating gate-all-around (GAA) structure, or a Large-area Nanostructure Array (LNA).

In the example shown in FIG. 1A, a device design 102 (shown by “models [1 . . . n]” 104a, 104b) of a simulated workpiece (i.e., for a processed semiconductor wafer (final processed or in-process) or microelectromechanical device) is simulated in a physics-based simulation 106 to generate simulated reflectance spectra profiles 108 (shown as 108a) of those models 104a, 104b, to be used as training data in an AI training system 110 along with the device design 102 to create a trained AI model for device design 112. Once trained, the trained AI model for device design 112 can be used in conjunction with measurements from metrology equipment 114 for a later fabricated device or workpiece 116 to generate predicted/estimated critical dimensions 118a/118b.

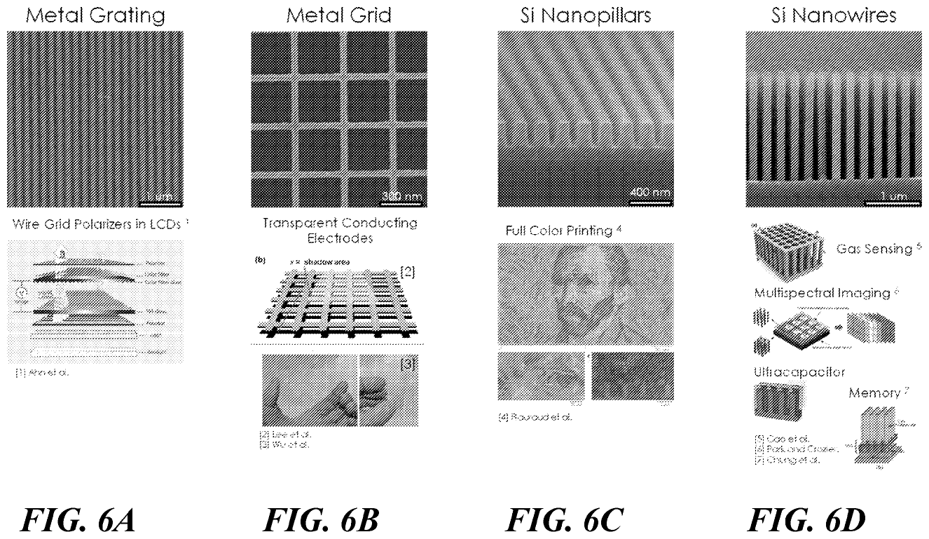

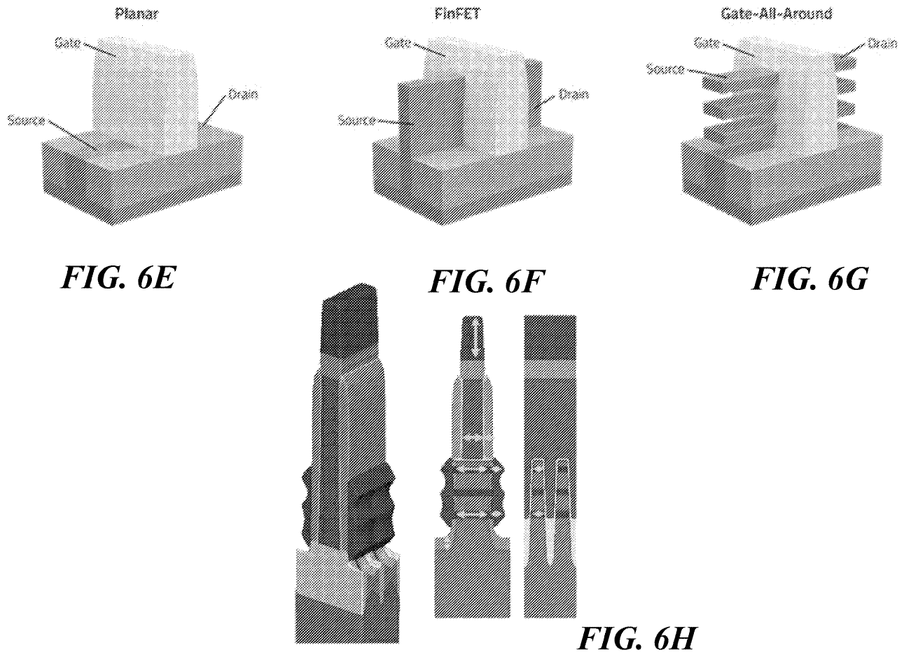

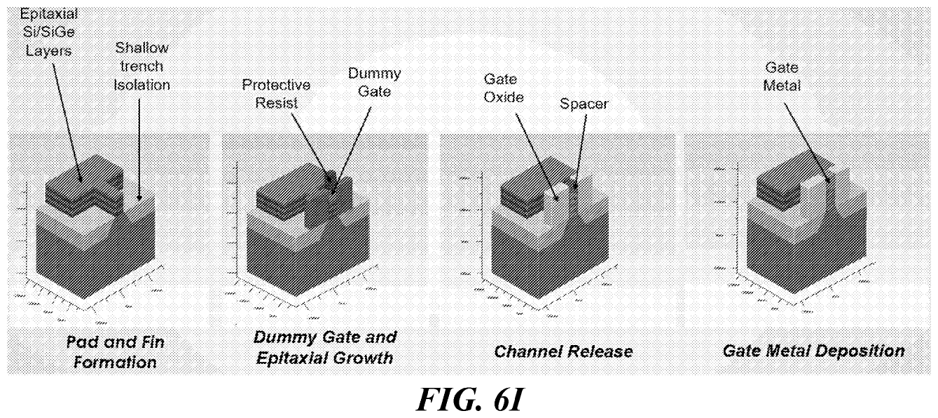

Specifically, each model [1 . . . n] (e.g., 104a, 104b) of the device design 102 includes design topology (i.e., geometric configuration), material, and a corresponding set of critical dimensions 118c for a semiconductor wafer or microelectromechanical device. The semiconductor wafer or microelectromechanical device, and corresponding model 104a has, throughout or in certain locations, an array of periodic microstructures or nanostructures. The 104a critical dimension 120 are provided to the AI training system 110 and to the physic-based simulation 106 and refers to a dimension of a microstructures or nanostructures to be fabricated in the semiconductor wafer or microelectromechanical device. The critical dimensions impact the semiconductor wafer's or microelectromechanical device's electrical, mechanical, dielectric, and/or functional properties. The models may be derived from high-level design (HLD) files, physical layout design files to which the material and geometric topology can generated by the physics-based simulation software 106. Diagram 122 shows an example array of periodic microstructures or nanostructures 124 and its corresponding expected critical dimensions 118a (shown as A, B, C, D, E, F, H, P). The model may be a monolithic structure, e.g., as shown in diagram 120, or a complex device structure, e.g., as shown in FIGS. 6E-6I.

The physic-based simulation 106 is configured, for each device design model 104a, 104b, to use the associated critical dimensions 120 of the device design model to produce a simulated reflectance spectra profile 108a for each of the [1 . . . n] models. A reflectance spectra profile is a unique profile that describes, for a given surface, how light is both reflected and absorbed by the surface. A reflectance spectra profile can be impacted by the surface material or structure, including microstructures or nanostructures. A reflectance spectra profile can be obtained for a single light wavelength and angle of incidence or across a range of light wavelengths and across a wave of angles of incidence. The simulated reflectance spectra profile 108a is computationally modeled for a given digital model 104a of a semiconductor wafer or microelectromechanical device. The physics-based simulation 106 is grounded in first-principles physics-based methods, such as rigorous coupled wave analysis or finite difference time domain (FDTD) approaches [18], and can be performed utilizing software packages, such as Lumerical [19].

The AI training system 110 is configured to train an AI model to predict the critical dimensions of a semiconductor wafer or microelectromechanical device. During the training, the AI training system 110 receives a model having a given set of critical dimensions as its input (ground truth) along with the corresponding simulated reflectance spectra profile 108a. The physics-based simulation 106 produces a plurality of simulated reflectance spectra profiles 108a for each of the [1 . . . n] models 104a, 104b to generate a library associating each simulated reflectance spectra profile 108a with the associated critical dimensions 120 of the model 104a. The generated library of the plurality of simulated reflectance spectra profiles and associated set of one or more critical dimension values, which can be generated using Latin Hypercube Sampling (or others), is used to train a trained AI model for device design 112.

Validation. In the example shown in FIG. 1A, following or in parallel to the training of the AI model 112, the device design having models [1 . . . n] 104 is also used for fabrication 126 of the device 116 having the device designs 102 for optional validation of the physics-based simulation 106. In the example shown in FIG. 1A, the fabrication 126 provides the fabricated device or workpiece 116, which may be fully processed or only partially processed. The fabricated device or workpiece 116 is next assessed with metrology equipment 114 to provide a measured reflectance spectra profile 108b of the fabricated device or workpiece 122. The measured reflectance spectra profile 118b is used for validation 128 of the simulated reflectance spectra profile 108a. If the simulated reflectance spectra profile 108a is sufficiently the same as the measured reflectance spectra profile 108b, the simulated reflectance spectra profile is input to the AI training system 110. The step of validation 128 aims to prevent the generated library from containing incorrect data, which would decrease the accuracy of the trained AI model for device design 112.

Fabrication 126 includes a series of nanopatterning steps that progressively shape the microstructure or nanostructures of the semiconductor wafer or microelectromechanical device, primarily via liquid etching and/or plasma etching.

Metrology equipment 114 employed for validation may include traditional metrology equipment that evaluate the micro or nanopatterned surfaces such as semiconductor wafers and microelectromechanical devices, e.g., using direct measurement, often through microscopy, and/or indirect measurement, often through scatterometry. Direct measurement can be performed via atomic force microscopy, scanning electron microscopy, or transmission electron microscopy. Direct measurement is typically destructive and is more suitable for batch assessment rather than quality assessment of an individual device. Indirect measurement can be performed via point-to-point scatterometry, spectral imaging scatterometry, or other suitable scatterometry techniques. Direct measurement can provide exact measured dimensions of a nanopatterned surface, whereas indirect measurement provides an indirect characteristic (e.g., reflectance spectra profile) that is influenced by the exact measured dimensions.

Because the trained AI model for device design 112 can evaluate variants of a device design for variant critical dimensions, the simulations of only a partial set of the device design are needed for the AI model training, which was observed to significantly improve the setup time for the evaluation of a given device sign over conventional matching evaluation that requires priori generated reference library of reflectance spectra to be simulated for an exhaustive set of possible underlying CDs characterizing the measured nanopatterns. Generating a training library, via the exemplary method, with a resolution sufficiently high to result in adequate accuracy of the predicted CDs, can be performed efficiency in terms of time, even for complex micro nanopatterns.

Referring still to FIG. 1A, following the training of the AI model, the trained AI model for device design 112 is then used during production operation to predict/estimate (i.e., determine) critical dimension values 118 (shown as 118a), or parameters derived therefrom, from metrology measurements of a fabricated semiconductor wafer or microelectromechanical device or intermediate workpiece. The trained AI model 112 (shown 112′) can receive the metrology measurement (e.g., measured reflectance spectra profile 108, shown as 108c) and generate, as its outputs, predicted/estimated critical dimensional values 118a, or the parameter derived therefrom, are then used, e.g., by quality/inspection assessment 130, to accept or reject (i) the fabricated semiconductor wafer or microelectromechanical device, (ii) a batch associated with the fabricated semiconductor wafer or microelectromechanical device, or (iii) equipment or process employed in the fabrication of the fabricated semiconductor wafer or microelectromechanical device.

In the example shown in FIG. 1A, during production operation for a device design 132, a given semiconductor wafer or microelectromechanical device is fabricated 126 (shown as 126′). At the beginning, during, or at the end of that set of processes, i.e., the device is fully or partially fabricated, or not at all, the fabricated device or workpiece 116 (shown as 116′) is measured by the metrology equipment 114 (shown as 114′) to produce reflectance spectra profiles 108c of the semiconductor wafer or microelectromechanical device 116′, e.g., at the various locations, wavelengths, and/or angles. The reflectance spectra profiles 108c are provided as inputs into the trained AI model 112′ for respective device design 132. The trained AI model 112 is capable of receiving the reflectance spectra profiles 108c and outputting critical dimensions 118a of the corresponding fabricated device or workpiece 116′. The predicted critical dimensions 118a, once outputted, are compared to the expected critical dimensions 118b in a quality/inspection assessment 130. The predicted/estimated critical dimensions 118a should be the same as the expected critical dimensions 118b, wherein “the same” can mean exactly identical or within a pre-defined tolerable error range (e.g., 1%-2%, less than 5%, less than 10%). In some embodiments, the tolerable error range can be based on the Gage R&R methodology. The fabricated device or workpiece 116′ is then rejected or accepted 134 based on its predicted critical dimensions 118a. The runtime segment 103a can be used for quality/inspection assessment 130 of a single fabricated device or workpiece 116′, a batch of fabricated devices or workpieces 116′ based on representative samples from the batch, or the process of fabrication 126 itself.

During the trained AI model 112, the measured reflectance spectra profiles 108c can be evaluated rapidly in real-time or near real-time. In addition to reducing the computation workload, the rapid evaluation can provide quality/inspection information that could be meaningful to adjust the current fabrication process for the current batch of devices or subsequent batch of devices. For example, if one of the fabrication processes or fabrication equipment was off-tuned, drifted, or miscalibrated, the real-time or near real-time information can inform a manufacturer to address that issue before subjecting additional workpieces to that fabrication process or fabrication equipment. The early detection could avoid rework or rejection of parts.

Additionally, the trained AI model 112 is capable of providing more granular evaluations of the micro or nano structures of the fabricated device or workpiece 116′. To this end, the evaluation can be performed with increased resolutions, e.g., extending prior evaluations at, for example, 1-15 CDs to 15-50 CDs in which additional metrics, e.g., angled surfaces and profiles of surfaces, can be additionally evaluated for anomalies.

Control Adjustments #1.FIG. 1B shows the exemplary system 100 (shown as 100b) can be performed for batch processing. Similar to the runtime segment 103a of FIG. 1A, in FIG. 1B, in runtime batch “1” 103b, a fabricated device or workpiece 116′ is fabricated and is evaluated by metrology equipment 114′ and the trained AI model to generate estimated critical dimensions 118a for control adjustments of the fabrication process or equipment in a later operation (shown as “runtime batch 2” 103c). In FIG. 1B, the estimated critical dimension 118a is compared to the expected critical dimension 118b to identify anomalies in the fabrication or production. The process adjustment 136 is then applied to the fabrication operation 126′, or associated equipment, for the next batch.

As an example, if the anomalous critical dimension is associated with a coating thickness or a channel size derived from an etching process, the degree of deviation of the estimated critical dimension 118a to the expected critical dimension 118b may be used directly or indirectly to adjust the etch time or the coating time for a process or equipment.

In some embodiments, the control operation may be performed in situ to a given fabrication machine or equipment having an external or internal metrology assessment component.

Control Adjustments #2(rolling fabrication). FIG. 1C shows the exemplary system 100 (shown as 100b) can be performed for rolling manufacturing processing. Similar to the runtime segment 103a of FIG. 1A, in FIG. 1C, in runtime step “1” 103d, a fabricated device or workpiece 140′ is fabricated and is evaluated by metrology equipment 114′ and the trained AI model to generate estimated critical dimensions 118a for control adjustments of the rolling fabrication process or equipment 138 (shown as 138′). In FIG. 1C, the estimated critical dimension 118a is compared to the expected critical dimension 118b to identify anomalies in the rolling fabrication or production 138′. The process adjustment 142 is then applied to the fabrication operation 138′, or associated equipment, for the next part of the roll.

As an example, if the anomalous critical dimension is associated with component placement for photovoltaic or flexible circuit being fabricated as a roll, the degree of deviation of the estimated critical dimension 118a to the expected critical dimension 118b may be used directly, or indirectly, to adjust placement positions of the components on the photovoltaic or flexible circuit on the roll.

In some embodiments, the control operation may be performed in situ on a given rolling fabrication machine or equipment having an external or internal metrology assessment component.

### Example Method of Metrology Optical Inspection

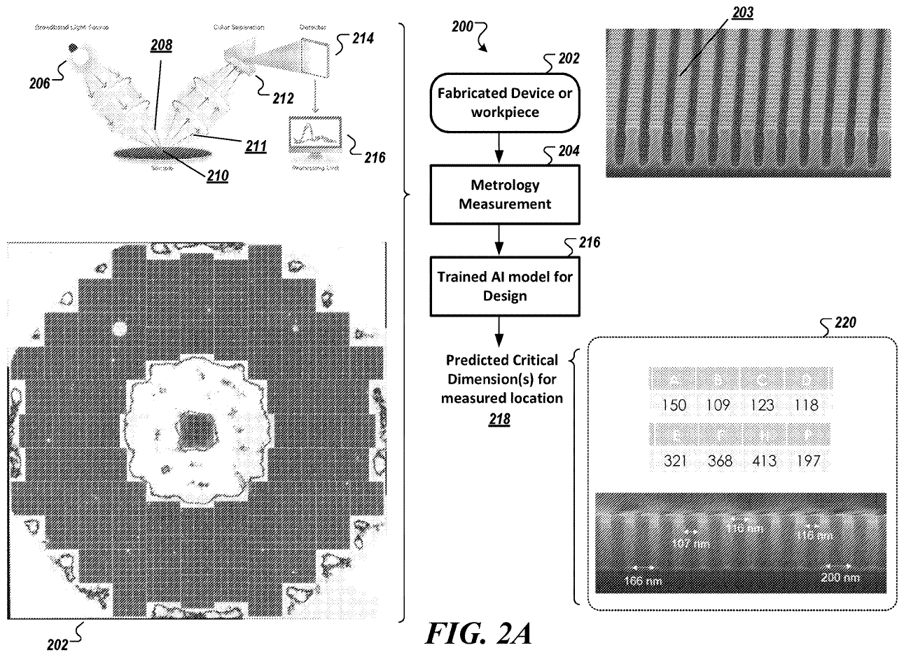

FIG. 2A shows an example method 200 of performing metrology measurement (e.g., scatterometry measurement) and prediction/estimation of critical dimensions for an exemplary fabricated device or workpiece (e.g., 116, 140′).

As shown in the example of FIG. 2, a fabricated device or workpiece 116 (shown as wafer 202) is provided that includes a periodic array of microstructure or nanostructure features 203 on the wafer 202. The metrology equipment exposes the wafer 202 a broadband light source 206 to generate a beam 208 that converges and shines on a portion 210 of the fabricated device 202 at point 210, within which is contained a portion of the periodic array of microstructure or nanostructure features 203. The microstructure or nanostructure features 203 interact with the beam 208 to which the size, shape, spacing, and material (as defined by critical dimensions) of the device 202 uniquely reflects the beam 208. In this example, in FIG. 2A, the reflected light (211) is passed through a color separator 212 and captured by a detector 214, which outputs a reflectance spectra profile 215 of the measured region of point 210. In some embodiments, the measurement is repeated in the same position using varying light wavelengths. In some embodiments, the light wavelength is varied between about 400 nm to about 700 nm. In some embodiments, the angle of incidence is varied between 0-90°. In some embodiments, multiple measurements are taken at various spatial positions of the fabricated device or workpiece. In some embodiments, multiple measurements are taken which cover the entirety of the fabricated device or workpiece. In some embodiments, measurements of only a portion of the fabricated device or workpiece can be used as representative measurements for the entire fabricated device or workpiece. Using the metrology measurement or measurements, the trained AI model 112 (shown as 216) can predict or estimate the critical dimensions 118a (shown as 218) for the measured location 218. Given the sensitivity of the reflectance spectra profile to the structure, variations in the critical dimensions of the part by either individual projections or across the whole fabricated device or workpiece would yield an altered reflectance spectra profile. Examples of critical dimensions 220 are also shown along with corresponding geometric structures.

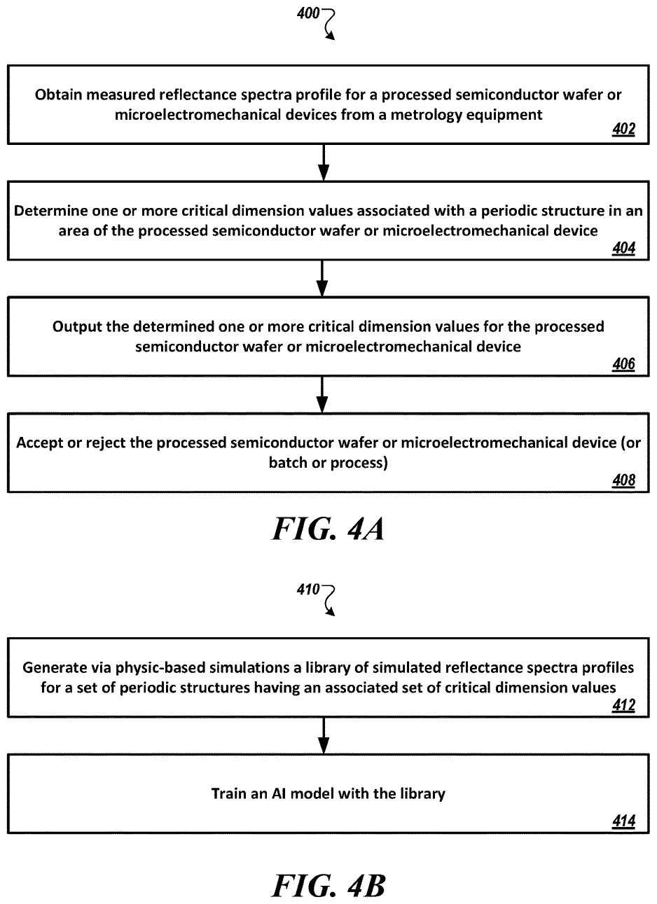

FIG. 4A shows a method 400. The first step 402 involves obtaining or receiving a measured reflectance spectra profile (e.g., multi-spectral data set or images, e.g., for a spot or an array) for one or more processed semiconductor wafer or microelectromechanical devices (e.g., a batch thereof) acquired by a piece of metrology equipment, including a processed semiconductor wafer or microelectromechanical device. The next step 404 involves determining, via an analysis operation using one or more trained machine learning models, using the measured reflectance spectra profile, one or more critical dimension values (e.g., structure can have between 1 and 50 CD values) associated with a periodic structure in at least one area, including a first area, of the processed semiconductor wafer or microelectromechanical device, wherein the one or more critical dimension values is determined by providing the measured reflectance spectra profile to the one or more trained machine learning models (e.g., XG-Boost or other ML algorithms). The next step 406 involves outputting the determined one or more critical dimension values for the processed semiconductor wafer or microelectromechanical device (e.g., in a report or in a control command). The final step 408 involves using the outputted one or more critical dimensional values, or a parameter derived therefrom, to accept or reject (i) the processed semiconductor wafer or microelectromechanical device, (ii) a batch associated with the processed semiconductor wafer or microelectromechanical device, or (iii) equipment or process employed in the fabrication of the processed semiconductor wafer or microelectromechanical device.

### Example Method of Training of AI Model for Metrology Optical Inspection

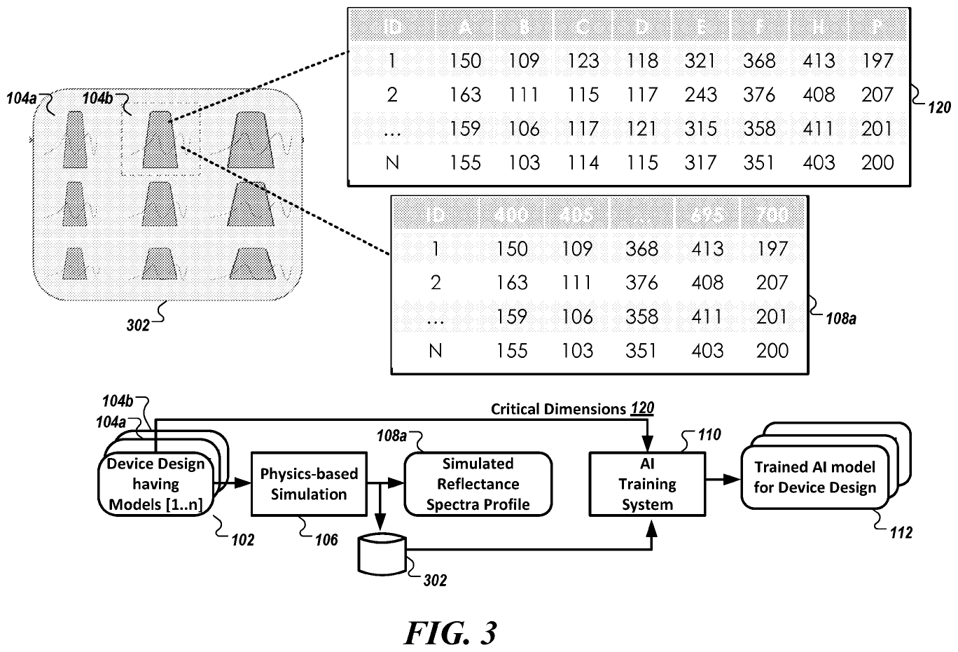

FIG. 3 shows an example method of training the exemplary AI model, e.g., described in relation to FIGS. 1A, 1B, and 1C. For a given device design 102 having models 104a, 104b, and a set of critical dimensions 120, in FIG. 3, a library 302 of simulated reflectance spectra profiles 108a is generated via the physics-based simulation 106.

FIG. 4B shows a method 410. Method 410 includes generating 412, via a physic-based simulation model (e.g., from a simulation software), a library (e.g., 302) of a plurality of simulation reflectance spectra profiles (e.g., 108) for a set of periodic structures in a semiconductor wafer or microelectromechanical device having an associated set of one or more critical dimension values. The method 410 then includes training (414) a machine learning/AI model using the generated library of the plurality of simulation reflectance spectra profiles and associated set of one or more critical dimension values.

The model can be used, for example, for the operation described in relation to FIG. 4A.

Machine Learning. Various analysis systems can be implemented using one or more artificial intelligence and machine learning operations. The term “artificial intelligence” can include any technique that enables one or more computing devices or computing systems (i.e., a machine) to mimic human intelligence. Artificial intelligence (AI) includes but is not limited to knowledge bases, machine learning, representation learning, and deep learning. The term “machine learning” is defined herein to be a subset of AI that enables a machine to acquire knowledge by extracting patterns from raw data. Machine learning techniques include, but are not limited to, logistic regression, support vector machines (SVMs), decision trees, Naïve Bayes classifiers, and artificial neural networks. The term “representation learning” is defined herein to be a subset of machine learning that enables a machine to automatically discover representations needed for feature detection, prediction, or classification from raw data. Representation learning techniques include, but are not limited to, autoencoders and embeddings. The term “deep learning” is defined herein to be a subset of machine learning that enables a machine to automatically discover representations needed for feature detection, prediction, classification, etc., using layers of processing. Deep learning techniques include but are not limited to artificial neural networks or multilayer perceptron (MLP).

Machine learning models include supervised, semi-supervised, and unsupervised learning models. In a supervised learning model, the model learns a function that maps an input (also known as feature or features) to an output (also known as target) during training with a labeled data set (or dataset). In an unsupervised learning model, the algorithm discovers patterns among data. In a semi-supervised model, the model learns a function that maps an input (also known as a feature or features) to an output (also known as a target) during training with both labeled and unlabeled data.

Neural Networks. An artificial neural network (ANN) is a computing system including a plurality of interconnected neurons (e.g., also referred to as “nodes”). This disclosure contemplates that the nodes can be implemented using a computing device (e.g., a processing unit and memory as described herein). The nodes can be arranged in a plurality of layers, such as an input layer, an output layer, and optionally, one or more hidden layers with different activation functions. An ANN having hidden layers can be referred to as a deep neural network or multilayer perceptron (MLP). Each node is connected to one or more other nodes in the ANN. For example, each layer is made of a plurality of nodes, where each node is connected to all nodes in the previous layer. The nodes in a given layer are not interconnected with one another, i.e., the nodes in a given layer function independently of one another. As used herein, nodes in the input layer receive data from outside of the ANN, nodes in the hidden layer(s) modify the data between the input and output layers, and nodes in the output layer provide the results. Each node is configured to receive an input, implement an activation function (e.g., binary step, linear, sigmoid, tanh, or rectified linear unit (ReLU), and provide an output in accordance with the activation function. Additionally, each node is associated with a respective weight. ANNs are trained with a dataset to maximize or minimize an objective function. In some implementations, the objective function is a cost function, which is a measure of the ANN's performance (e.g., an error such as L1 or L2 loss) during training, and the training algorithm tunes the node weights and/or bias to minimize the cost function. This disclosure contemplates that any algorithm that finds the maximum or minimum of the objective function can be used for training the ANN. Training algorithms for ANNs include but are not limited to backpropagation. It should be understood that an ANN is provided only as an example machine learning model. This disclosure contemplates that the machine learning model can be any supervised learning model, semi-supervised learning model, or unsupervised learning model. Optionally, the machine learning model is a deep learning model. Machine learning models are known in the art and are therefore not described in further detail herein.

A convolutional neural network (CNN) is a type of deep neural network that has been applied, for example, to image analysis applications. Unlike traditional neural networks, each layer in a CNN has a plurality of nodes arranged in three dimensions (width, height, and depth). CNNs can include different types of layers, e.g., convolutional, pooling, and fully-connected (also referred to herein as “dense”) layers. A convolutional layer includes a set of filters and performs the bulk of the computations. A pooling layer is optionally inserted between convolutional layers to reduce the computational power and/or control overfitting (e.g., by downsampling). A fully-connected layer includes neurons, where each neuron is connected to all of the neurons in the previous layer. The layers are stacked similarly to traditional neural networks. GCNNs are CNNs that have been adapted to work on structured datasets such as graphs.

Other Supervised Learning Models. A logistic regression (LR) classifier is a supervised classification model that uses the logistic function to predict the probability of a target, which can be used for classification. LR classifiers are trained with a data set (also referred to herein as a “dataset”) to maximize or minimize an objective function, for example, a measure of the LR classifier's performance (e.g., an error such as L1 or L2 loss), during training. This disclosure contemplates that any algorithm that finds the minimum of the cost function can be used. LR classifiers are known in the art and are therefore not described in further detail herein.

A Naïve Bayes' (NB) classifier is a supervised classification model that is based on Bayes' Theorem, which assumes independence among features (i.e., the presence of one feature in a class is unrelated to the presence of any other features). NB classifiers are trained with a data set by computing the conditional probability distribution of each feature given a label and applying Bayes' Theorem to compute the conditional probability distribution of a label given an observation. NB classifiers are known in the art and are therefore not described in further detail herein.

A k-NN classifier is an unsupervised classification model that classifies new data points based on similarity measures (e.g., distance functions). The k-NN classifiers are trained with a data set (also referred to herein as a “dataset”) to maximize or minimize a measure of the k-NN classifier's performance during training. This disclosure contemplates any algorithm that finds the maximum or minimum. The k-NN classifiers are known in the art and are therefore not described in further detail herein.

### Example Nanostructures and Processes

FIGS. 6A-6D show example fabrication operations to fabricate metal grating structures, metal grid structures, nanopillars, and nanowires. Metal grating structures are fabricated for polarizers in liquid crystal displays. Metal grid structures are used to fabricate transparent conducting electrodes. Nanopillars and nanowires are employed as sensors for gas sensing, multispectral imaging, ultracapacitors, and memory devices, among other applications.

FIGS. 6E-6I shows examples of LNAs with complex geometries. FIG. 6E shows a planar FET. FIG. 6F shows a FinFET. FIG. 6G shows a gate-all-around (GAA) transistor structure. The stacked silicon sheets can offer improved control of current flow. GAA transistors can be scaled to smaller sizes than existing designs. FIG. 6I shows another GAA transistor structure and an example fabrication sequence.

Indeed, the exemplary system and method may be used to evaluate LNAs with deep, high-aspect ratio features, LNAs with horizontal and vertical holes, and other complex patterns described or referenced herein.

### Experimental Results and Additional Examples

A study was conducted to develop and evaluate a rapid optical metrology methodology of CDs for complex nanopatterned surfaces through the use of a machine learning-based inverse problem coupled with the use of optimal feature selection algorithms. The study used Latin Hypercube Sampling to create a multi-dimensional grid of CDs to be used as inputs for simulations to build the training data. An extreme gradient boosting (XGBoost) algorithm was utilized for the CD estimation. In addition, important wavelengths were detected using the Recursive Feature Elimination (RFE) algorithm utilizing feature important scores obtained from XGBoost. The capabilities of the newly proposed approach were evaluated through the inspection of semiconductor wafer samples with hourglass patterns characterized by eight CDs. It was observed that one can obtain significantly faster CD measurements compared to inspection times associated with scanning electron microscopy (SEM) as well as optimization-based inverse problem methods while at the same time improving the Gage R&R ratios associated with SEM-based inspection. In conclusion, this method enables dramatically faster yet accurate and reliable metrology of CDs of large area nanopatterned surfaces with complex nanostructure arrays.

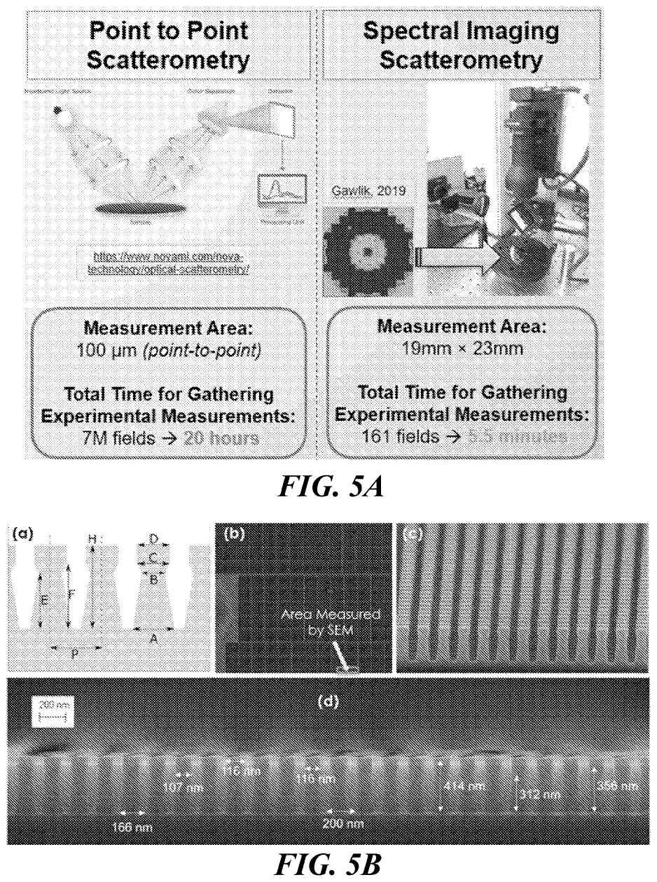

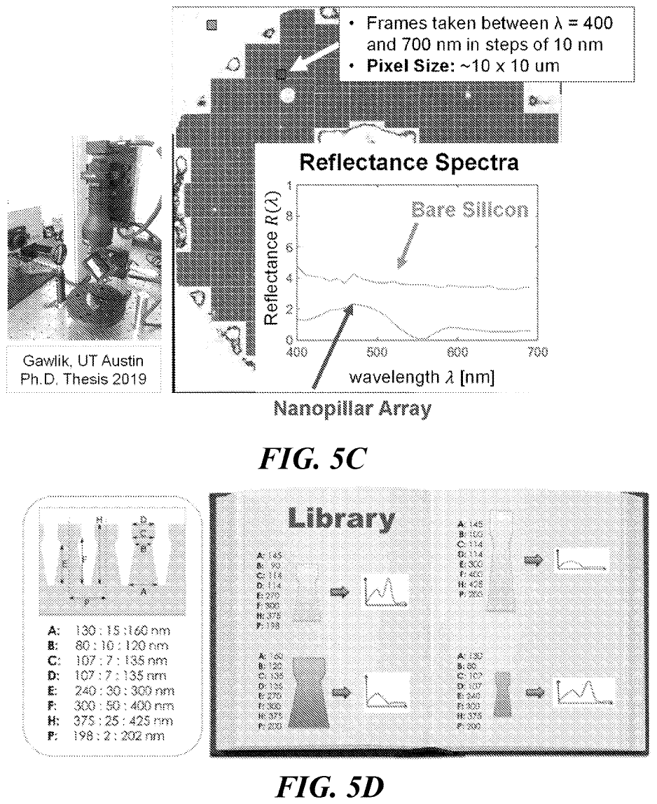

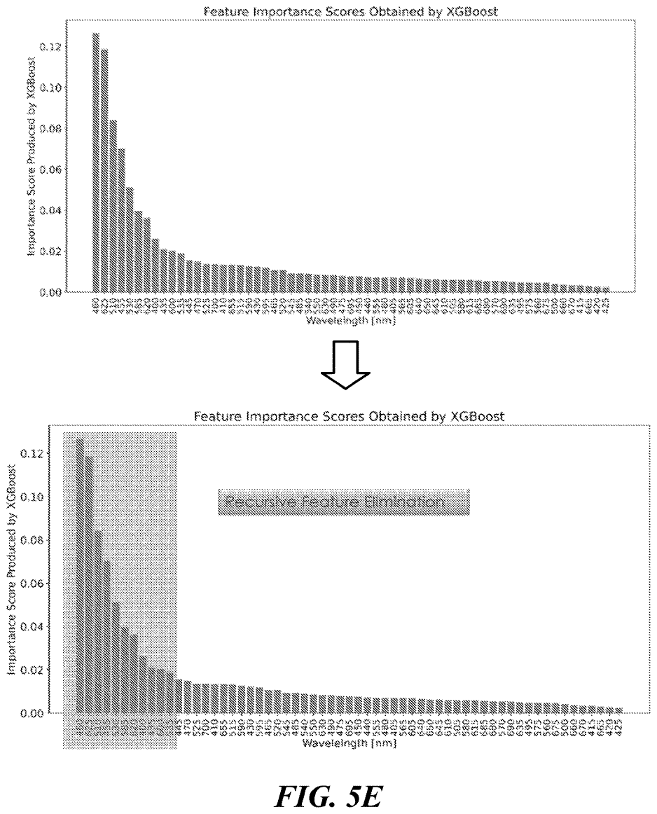

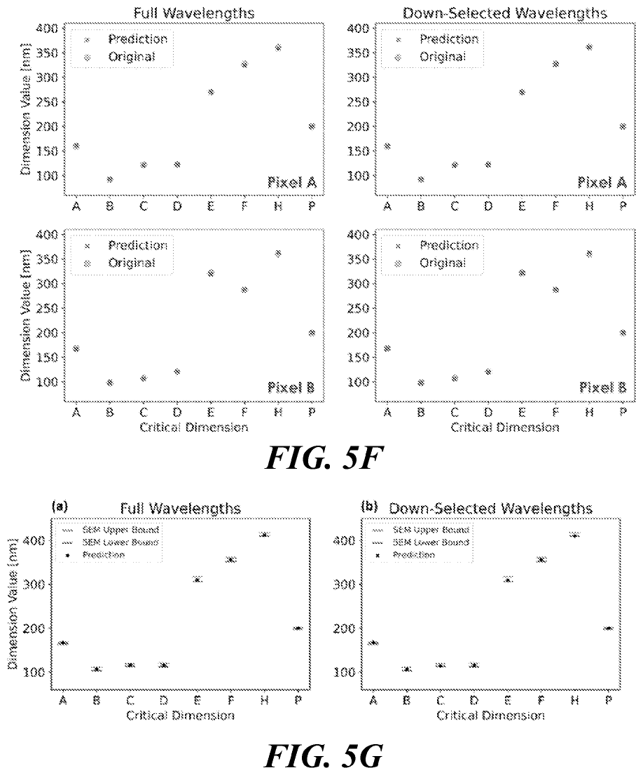

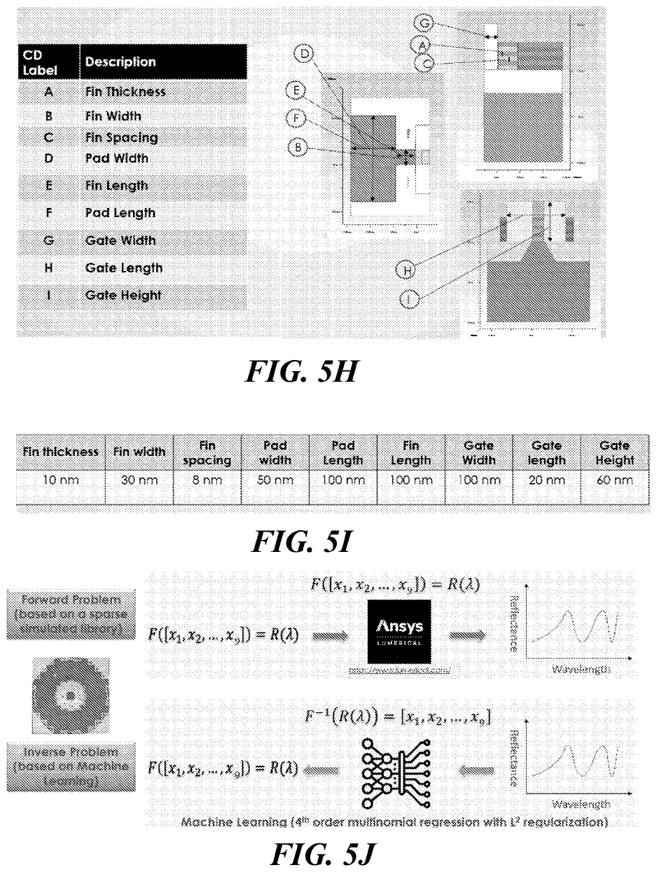

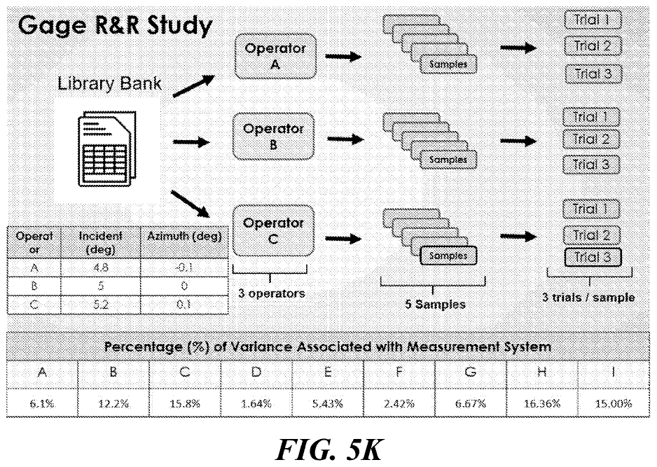

Rapid Training System. The study evaluated the developed methodology for rapid optical inspection of CDs of LNAs on a semiconductor wafer sample with nanoscale hourglass patterns fabricated on it. FIG. 5A shows measurements performed in the study using point-to-point scatterometry and spectral imaging scatterometry. FIG. 5A, SEM-based measurements of the eight pertinent CDs were obtained as average measurements of CDs of ten different hourglass features in multiple locations of the same sample, as estimated using ImageJ software [119]. The study investigated how quick, accurate, repeatable, and reproducible the proposed method is in obtaining the CD values associated with the actual hourglass wafer sample. Those metrics were then compared with SEM-based metrology performance, as well as with the performance metrics of methods reported in [12], and [24].

Simulated reflectance spectra. The total dataset of simulated reflectance spectra consisted of 30,000 simulations conducted using Lumerical software based on 61 wavelengths, with CD combinations generated using LHS for an a priori-specified range of CD values. This dataset was split into training and testing portions, with randomly selected 75% of the data being in the training portion. RandomizedSearchCV was used to evaluate 500 different combinations of the six important XGBoost hyperparameters. The average training time required for the evaluation of each hyperparameter combination was about 2-3 minutes, and the entire hyperparameter tuning took about 20 hours on a standard PC. The best hyperparameter set was identified as the one with the smallest RMSE between XGBoost-predicted CDs and CDs used for simulations of the corresponding reflectance spectra.

FIG. 5B shows an example nanopatterned structure evaluated in the study. FIG. 5C shows an example equipment and the difference in reflectance spectra between a bare silicon sample and a sample with nanopillar arrays. FIG. 5D shows simulated reflected spectra for a set of different nanostructure designs. The CDs in FIG. 5D are examples of expected CDs (e.g., 118b).

FIG. 5E shows feature importance scores evaluated by the XGBoost model [131], with the best-performing hyperparameter set clearly illustrating that some wavelengths seem to carry much more information than others.

To identify the most informative set of spectral wavelengths, the RFE feature selection algorithm was utilized based on the feature importance scores given by the XGBoost model. RFE algorithm detected that out of 61 wavelengths, only the top 11 wavelengths with the highest importance scores are sufficient to accurately estimate the CDs of hourglass samples.

Training time for XGBoost with the full set of spectral wavelengths was 325 seconds, while the training time for XGBoost using only the most informative wavelengths took just 47 seconds on a standard PC. The predictive performance of the XGBoost models was then evaluated on the testing dataset for both the full and down-selected wavelength sets. Those predictive capabilities are visually illustrated in FIG. 5F, which, for two randomly selected spectra from the test dataset, shows XGBoost-predicted CDs, alongside CDs for which those reflectance spectra were simulated. Just visual inspection of FIG. 5F indicates similarity in performance of the XGBoost-based CD predictions using full and down-selected sets of wavelengths. This point is more thoroughly depicted by the results reported in Table 1, which summarizes several accuracy metrics of XGBoost-based CD predictions obtained using the full and down-selected sets of wavelengths, as evaluated on the entire testing dataset.

ML Model: The study created a dataset of simulated reflectance spectra for a range of possible CDs characterizing the target nanopattern, based on which the ML model can be trained. In the study, Latin Hypercube Sampling (LHS) algorithm was used as the trained model. LHS is a statistical method for generating a near-random sample of parameter values from a multidimensional distribution. In the context of statistical sampling, a square grid containing sample positions is a Latin square if and only if there is only one sample in each row and each column. A Latin hypercube is the generalization of this concept to an arbitrary number of dimensions, whereby each sample is the only one in each axis-aligned hyperplane containing it. The main advantage of the LHS approach is that it produces samples that reflect the true underlying distribution and is able to do so with much smaller sample sizes than what simple random sampling would require [130]. The method of sampling employed in the study can be particularly advantageous if one is working with data that has a high number of dimensions and needs to obtain random samples that are of a reasonable size while still being able to reflect the true underlying distribution of the data. In the case of optical metrology of LNA CDs, utilizing the LHS method can lead to a richer library compared to a library of the same size generated by an exhaustive, rectangular grid of CDs utilized in [24].

The study used the Extreme Gradient Boosting (XGBoost) algorithm in addressing the inverse problem mapping for the optical metrology of CDs of LNAs. The XGBoost algorithm is an ensemble-ML method that sequentially utilizes several simpler decision trees, with each subsequent tree aiming to reduce the errors of the previous tree in order to improve the final prediction accuracy. In each future tree, the XGBoost utilized data points with the lowest prediction performance more frequently so that the model learns about such data points more intensely, which enables it to perform better than general artificial neural networks-based algorithms when it comes to small to medium size training data [132]. It was observed that this was highly adequate for the problem considered in the study because of the need to train the underlying ML models using as few simulations as possible.

The study employed over 20 hyperparameters in the XGBoost training. The study relied on recent research that demonstrated that six of the hyperparameters have the most effect on the prediction performance, i.e., having the highest probability of rapidly yielding the most accurate, unbiased results without over-fitting [134]. Consequently, to perform hyperparameter tuning, the study employed a Python built-in Randomized Search Cross-Validation (RandomizedSearchCV) method to find the combination of those six hyperparameters which yielded the best predictive performance of the XGBoost ML model.

In the study, the XGBoost model was set up with inputs being reflectance spectra obtained using first-principles physics-based simulations and outputs being the CDs for which those simulations were conducted. The data was then split into training and test datasets, with 5-fold cross-validations performed during training to avoid overfitting. The study evaluated the ML model on the test dataset via comparison of the XGBoost-predicted CD values and corresponding CD values utilized in the physics-based simulations of the reflectance spectra. Root Mean Square Error (RMSE), Mean Absolute Error (MAE), and adjusted R² were used as metrics for evaluating the accuracy of the ML-based model realizing the inference of CDs. After tuning the relevant hyperparameters in the XGBoost and validating the accuracy of its CD estimation on the test dataset, the study trained the final XGBoost model using the entire reference library of simulated reflectance spectra and corresponding CDs. This model was then used as the predictor of underlying CDs when experimentally acquired reflectance spectra collected from a hyperspectral imaging system were presented to it as inputs.

It was observed that exhaustive feature sets as inputs for ML-based tasks, such as regression, classification, or clustering problems, prolonged the underlying training process and often led to overfitting issues, where the ML model learns very detailed characteristics about the training data, while losing its ability to generalize to other datasets. Consequently, the Recursive Feature Elimination (RFE) method was used to efficiently select the most informative spectral wavelengths. Given an ML model that assigns weights to features (e.g., the feature importance scores in XGBoost), the RFE method starts with a full set of input features, trains the model with available features, and drops the least important one. RFE repeated the process recursively until dropping a feature significantly reduces the prediction accuracy. The RFE method was observed to be compatible with ensemble methods, such as XGBoost, and was applied directly to the trained models to identify the model inputs with significant predictive capabilities [138]. The reduced feature set obtained by the RFE method was then used to enable XGBoost-based CD inference through hyperparameter tuning, model training, and validation.

Down-selection operation. The study further implemented techniques to accelerate the training using optimized down-selection of spectral wavelengths involved in the inspection process. Specifically, Latin Hypercube Sampling is utilized to create a set of CD vectors, which are used as inputs for physics-based simulations of reflectance spectra expected from the corresponding nanopatterned surface (done using commercially available software—e.g. Lumerical). These CDs and spectra are then used as the training data set for the ML-based realization of the inverse problem (for building the ML model that relates actually obtained reflectance spectra back to the corresponding CDs). In addition, important spectral wavelengths are down-selected using optimized feature selection algorithms adapted from game theory, thus reducing the number of wavelengths involved in the process of CD inference (methods such as Random Forest Feature Importance Score, Permutation-based Feature Importance, or Shapley Importance Score can be used for the downselection purpose). Finally, an extreme gradient boosting (XG-Boost) regressor is utilized for the CD estimation from the observed reflectance spectra (observed reflectance spectra are used as inputs for the XG-boost regressor).

Gage R&R Analysis. To formally assess the capabilities of the method in the study, the study conducted Gage R&R to formally evaluate for reflectance spectra-based inspection using XGBoost models inferring CDs from both the full and reduced sets of wavelengths. The Gage R&R values were compared to that of SEM-based metrology, whose accuracy and precision are generally considered adequate for this metrology task, as well as to Gage R&R values corresponding to reflectance spectra-based metrology and CD inference methods described in [12], and [24]. A standard Gage R&R procedure described in was utilized in this study, with two participating operators, five parts (i.e., pixel areas), and three repetition trials, meaning that for a specific part and a specific operator, the same reflectance spectrum-related pixel area was measured three times. Repeatability, reproducibility, and Gage R&R ratios were evaluated separately for each CD of the underlying pattern.

Results. Table 1 shows the accuracy metrics for CD estimation using XGBoost with the best-performing hyperparameters.

TABLE 1

| | Full Wavelengths | | | Down-Selected Wavelengths | | |
|---|---|---|---|---|---|---|
| Critical | | | Adjusted | | | Adjusted |
| Dimension | RMSE | MAE | R² | RMSE | MAE | R² |
| A | 0.4176 | 0.3196 | 0.9967 | 0.5179 | 0.3968 | 0.9948 |
| B | 1.0843 | 0.7485 | 0.9773 | 1.1707 | 0.8231 | 0.9734 |
| C | 2.9935 | 2.1853 | 0.7261 | 3.2791 | 2.4326 | 0.6718 |
| D | 3.3132 | 2.4450 | 0.6717 | 3.5716 | 2.7140 | 0.6212 |
| E | 6.4185 | 4.4183 | 0.9130 | 7.4835 | 5.3952 | 0.8811 |
| F | 7.2943 | 5.4943 | 0.8856 | 8.6882 | 6.4076 | 0.8385 |
| H | 6.7511 | 3.9068 | 0.9129 | 6.9420 | 4.1443 | 0.8975 |
| P | 0.3151 | 0.2503 | 0.9999 | 0.3243 | 0.2963 | 0.9998 |
| Total | 4.4899 | 2.4397 | 0.7594 | 4.9972 | 2.7892 | 0.7346 |

To verify the accuracy, repeatability, and reproducibility of the proposed ML-based optical metrology method, CDs associated with the actual wafer sample with hourglass patterns fabricated on it were inspected. FIG. 5G shows predicted CDs for one experimentally acquired pixel from the sample shown in FIG. 5F, using XGBoost models trained with spectra containing the full and down-selected sets of wavelengths. It also shows upper and lower bounds of a 95% confidence interval of CD measurements obtained via SEM metrology. We can observe that both XGBoost models can accurately predict the CDs of hourglass patterns well inside the 95% confidence intervals for all eight CDs characterizing hourglass patterns.

Table 2 shows the Gage R&R ratios obtained from the cross-section of the wafer sample area shown in FIG. 5G, subpanel (b). It can be observed that the process is repeatable for multiple locations, multiple operators, and multiple samples, as shown in Table 2. Gage R&R ratios were evaluated for the XGBoost-based CD inference using both the full and down-selected wavelength sets. Additionally, the Gage R&R ratios were assessed for optical metrology and for the SEM inspection of the same pixel area. Results show that the newly proposed XGBoost-based CD inference methods using either the full or the down-selected wavelength sets provided better Gage R&R ratios compared to SEM-based inspection, which is generally considered as the most accurate alternative for LNA metrology purposes.

TABLE 2

| | Critical Dimensions | | | | | | | |
|---|---|---|---|---|---|---|---|---|
| Metrology Methods | A | B | C | D | E | F | H | P |
| ML-based Optical Metrology of | 8.3 | 8.7 | 9.2 | 10.4 | 10.6 | 9.3 | 8.9 | 7.6 |
| CDs trained by full set of | | | | | | | | |
| wavelengths | | | | | | | | |
| ML-based Optical Metrology of | 8.6 | 8.9 | 9.6 | 11.2 | 10.9 | 10.1 | 9.1 | 8.3 |
| CDs trained by down-selected | | | | | | | | |
| wavelengths | | | | | | | | |
| Inverse problem-based Optical | 12.2 | 9.9 | 12.5 | 10.5 | 7.4 | 4.4 | 12.5 | 10.6 |
| Metrology of CDs proposed in | | | | | | | | |
| Chapter 4 | | | | | | | | |
| Scanning Electron Microscopy | 9.8 | 12.7 | 9.8 | 11.3 | 13.5 | 12.9 | 9.1 | 11.7 |
| (SEM) | | | | | | | | |

Table 3 demonstrates the time needed to perform CD inspection for a full 300 mm wafer with hourglass patterns fabricated on it using the newly proposed rapid optical metrology of CDs, as well as alternative inspection methods. Experimental measurements and CD inferences are repeated for each wafer. One can observe from the results reported in Table 6 that utilizing the novel metrology method proposed in this study can achieve inspection and CD inference of a full 300 mm wafer with hourglass patterns within minutes. This should be sufficiently fast for full in-process inspection of every wafer, which, in turn can lead to greatly improved process and quality control.

TABLE 3

| | | | Library/Training | | | |
|---|---|---|---|---|---|---|
| | Experimental | | Data Creation | | CD | |
| Metrology Method | Measurement | | (one time action) | | Inference | |
| Scanning Electron Microscopy | ~80 | days | 0 | | ~20 | days |
| Point-to-point scatterometry | 20 | hours | >100 | years | >4 | years |
| Imaging-based optical | 5.5 | minutes | >100 | years | >4 | years |
| scatterometry metrology of CDs | | | | | | |
| proposed in [12] | | | | | | |
| Imaging-based optical | 5.5 | minutes | >100 | years | ~4 | months |
| scatterometry metrology of CDs | | | | | | |
| with efficient search proposed in | | | | | | |
| [23] (Chapter3) | | | | | | |
| Inverse-problem-based optical | 5.5 | minutes | 10 | days | 3 | days |

| | | | | | |
|---|---|---|---|---|---|
| metrology of CDs proposed in [24] | | | | | |
| (Chapter 4) | | | | | |
| Exemplary ML-based optical | 5.5 | minutes | 7 days for library | 5 | hours |
| metrology of CDs using full set of | | | creation | | |
| wavelengths - one core | | | 325 seconds for ML | | |
| | | | model training | | |
| Exemplary ML-based optical | 1 | minute | 7 days for library | 30 | minutes |
| metrology of CDs using down- | | | creation | | |
| selected wavelengths - one core | | | 47 seconds for ML | | |
| | | | model training | | |
| Newly proposed ML-based | 5.5 | minutes | 7 days for library | 3 | minutes |
| optical metrology of CDs using | | | creation | | |
| full set of wavelengths - 100 | | | 200 seconds for ML | | |
| parallel cores | | | model training | | |
| Newly proposed ML-based | 1 | minute | 7 days for library | 3 | minutes |

| | |
|---|---|
| optical metrology of CDs using | creation |
| down-selected wavelengths - 10 | 20 seconds for ML |

| | |
|---|---|
| parallel cores | model training |

Gage R&R Study of GAA structure. The study additionally performed Gage R&R evaluation of a complex device to validate the exemplary system and method. The study observed that that the exemplary system and method indeed provide tremendous opportunity to quickly (within minutes) and accurately (Gage R&R of 15% or less) inspect large areas of nanopatterned surfaces with complex periodic structures (e.g. large areas with GAA transistors). The study also observed the possibility to use the exemplary system and method for rapid focusing of defectivity inspection on “anomalously-looking” wafer areas.

FIG. 5H shows the critical dimensions employed for the GAA device in the Gage R&R evaluation. Nine CDs are shown for the structure which were allowed to be modified for the evaluation. While complex, the structure is periodic.

FIG. 5I shows an example value for the nine CDs. The three most important critical dimensions and their ranges as gathered from literature [150]-[154] were: Fin Width: 15-100+nm, Fin Thickness: 5-50 nm, Gate Length: 12 nm-60 nm but mostly close to 12 nm. Fin Spacing is usually a few nanometers smaller than Fin Thickness. Gate Height is typically depicted in diagrams to be slightly taller than a triple stack fin, but exact dimensions vary. S/D pad dimensions (length, width) are ad-hoc.

FIG. 5J shows a summary of the ML training to provide the rapid inference of the CDs. 10,000 simulated spectra for varied device topologies were employed in the training of five ML models, and 2,000 simulated spectra were employed for validation of the training (randomly chosen). The ML training employed L2 regularization hyper-parameters optimized through a 5 fold cross validation on the training dataset. L2 regularization was chosen to reduce or avoid over regularization. 61 wavelengths were employed in the simulated device and CDs having a range of 400 to 700 nanometers in 5 nm steps.

FIG. 5K shows the Gage R&R evaluation and subsequent results. Three simulated operators were evaluated via simulation. During their respective simulated measurement, different incident angle and azimuth angle of the acquisition for each of the operators were applied; that is, each operator was simulated to acquire their measurement differently from one another, to provide variability in the measurement. Five samples were simulated as being acquired for a given trial, and three trials were performed for each sample. The results (percentage of variance) show accurate Gage R&R with variance of 1.64% to 16.67% in the observed CDs.

Discussion. An inverse problem in science can be seen as the process of calculating from a set of observations the causal factors or inputs that produced them [83]. Inverse problems are commonly used in science and mathematics to determine parameters that one cannot directly observe, or their direct observation is expensive or time-consuming [84][85], as is the case in optical metrology of CDs in LNAs. Applications of inverse problems can be found in geoscience [86][87], weather forecasting [88], oceanography [89], medical imaging [90][91], chemistry [92][93], biology [94], pharmaceutical industries [95], machine learning [96][97], computer vision [98][99], nondestructive testing [100], and many other disciplines.

Due to their ability to model complex dependencies using large amounts of data and to rapidly evaluate those models, the use of ML-based methods to solve complex inverse problems recently received significant attention in various application fields, including imaging [123][124], topological photonics [125], chemistry [126], geodynamics and semiconductor manufacturing [128]. A study was conducted that intended to pursue the same direction and realize inference of CDs of complex LNAs through an ML-based inverse problem realization rather than time-consuming and computationally demanding optimization, as was done in [24].

### DISCUSSION

Advancements in nano-fabrication techniques, coupled with a deeper understanding of the physics behind nanophotonic phenomena, have facilitated the pursuit of novel industrial-scale manufacturing processes. Specifically, modern high-throughput nanopatterning techniques, such as nanoimprint lithography [4], have enabled the fabrication of Large-area Nanostructure Arrays (LNAs) on a variety of substrates, including silicon wafers, glass sheets, and flexible roll-to-roll webs, reaching scales as large as cm2 or m2. This has permitted the design and manufacturing of a wide array of products, including optical devices, such as wire-grid polarizers [5], transparent conductors [6], color filters [7], and anti-reflection surfaces [8], as well as building blocks for electronic components, such as ultra-capacitors [9], optical sensors [10], and memory storage architectures [11].

However, metrology approaches have fallen behind advancements in fabrication and are not amenable to high manufacturing throughputs. Traditionally, these nanopatterns are measured by direct approaches, such as Scanning Electron Microscopy (SEM)-based inspection [41], or Atomic Force Microscopy (AFM)-based metrology [44]. Due to their small field of view and slow measurement processes, they are orders of magnitude away from being able to accomplish in-cycle inspection of LNAs.

It was recently demonstrated that scatterometry-based metrology has the capability to significantly accelerate the inspection of LNAs and can be seen as a fast, non-contact, non-destructive alternative to microscopy-based inspection methods [13][14]. Scatterometry-based metrology of geometric characteristics of LNAs utilizes first-principles physics-based dependencies between the reflectance spectra of light scattered from a nanopatterned surface and relevant geometric parameters, or so-called Critical Dimensions (CDs), of periodic structures in the LNA. State-of-the-art scatterometry-based metrology techniques are ellipsometric scatterometry and angular scatterometry methods. In the case of ellipsometric scatterometry, the angle of incidence of the light is fixed, while the wavelengths are varied [14][15]. Conversely, in the case of angular scatterometry, the angle of incidence is varied, while a fixed wavelength source, usually a high-brightness laser source, is used [53][122]. In either case, the scatterometry-based metrology approaches consist of 3 major steps: (i) one-time, offline generation of a library of reflectance spectra through first-principles physics-based simulations conducted for a set of CDs characterizing the inspected nanopattern shape; (ii) experimental acquisition of reflectance spectra from a specified area; and (iii) fr each experimentally acquired reflectance spectrum, a search within the library of simulated reflectance spectra to find the best matching simulated spectrum, with CDs corresponding to that best matching simulated spectrum being identified as the CDs associated with the area from which that experimental reflectance spectrum was obtained.

Each of the steps listed above is associated with challenges when it comes to the need to perform them quickly while ascertaining sufficient accuracy of the resulting metrology process.

The measurement acquisition step in ellipsometric scatterometry-based LNA metrology is significantly accelerated in by parallelizing the acquisition of reflectance spectra. This was enabled by a novel design of an ellipsometric scatterometry-based metrology device, which facilitated concurrent acquisition of over 5 million reflectance spectra, each coming from a μm2-scale area within a 19×23 mm² field of view. It enabled the acquisition of reflectance spectra from the surface of a 300 mm wafer within 5.5 minutes, which is at the order of magnitude of relevant unit semiconductor manufacturing processes and can be improved even further with a better camera and a larger field of view.

When it comes to the step of identifying the best match of an experimentally acquired reflectance spectrum, that step is far from trivial, especially when one understands that over 5 million reflectance spectra come from each field of view, and that for each one of them, the offline generated library needs to be efficiently searched for the best match. That step was greatly accelerated in [23] by organizing the reference library of reflectance spectra into a tree-structured database via unsupervised clustering implemented using a growing self-organizing map mechanism [32]. Such database indexing allowed logarithmic acceleration of searches within reference libraries of simulated reflectance spectra, which is of paramount importance, especially when those reference libraries become large.

The most recent improvements in the realm of reflectance spectra-based metrology of LNA CDs came at the stage of reference library generation [24]. Namely, previous implementations of this inspection method required a dense library of simulated reflectance spectra corresponding to an exhaustive grid of possible CDs characterizing the inspected LNA. The density of that grid needed to be with a sufficient CD resolution so that the best matches could be located within that library with adequate accuracy. Generation of such a dense library is feasible for periodic structures of relatively simple geometries characterized by just a few CDs. For example, in [12], authors inspected arrays of truncated cones, which are characterized by only 3 CDs, and the exhaustive library of reference reflectance spectra was generated within about a day via simulations using Lumerical software. However, if one wishes to inspect a nanopatterned wafer with hourglass-shaped structures which are characterized by 8 CDs, the creation of an exhaustive library with the same resolution would take over 100 years on a regular Personal Computer (PC). Indeed, creating an exhaustive reference library of reflectance spectra does not scale well with the complexity of patterns, and this problem was recently addressed in [24]. The method reported in [24] starts with a sparse initial library of simulated reflectance spectra that can be feasibly generated, based on which an optimization-based inverse problem is utilized to efficiently guide further simulations in order to sufficiently match those simulations with the experimentally acquired reflectance spectra and thus obtain the underlying CDs with desired accuracy. The method enabled metrology of hourglass patterns with an initial reflectance spectra library generated within several days (instead of 100 years), and the resulting Gage Repeatability and Reproducibility (Gage R&R) was comparable to that of SEM-based metrology.

However, even though the research reported in [24] facilitated orders of magnitude faster measurements of LNA CDs while at the same time maintaining the Gage R&R of SEM-based inspection, the time needed to fully measure a 300 mm wafer with hourglass nanostructures is still outside the unit process cycle times of such wafers (hours instead of minutes). Hence, significant improvements are still needed to further accelerate reflectance spectra-based inspection of LNAs while at the same time minimally or not at all jeopardizing its accuracy and Gage R&R.

### CONCLUSION

Throughout the description and claims of this specification, the word “comprise” and other forms of the word, such as “comprising” and “comprises,” means including but not limited to, and are not intended to exclude, for example, other additives, segments, integers, or steps. Furthermore, it is to be understood that the terms comprise, comprising, and comprises as they relate to various aspects, elements, and features of the disclosed invention also include the more limited aspects of “consisting essentially of” and “consisting of.”

As used herein, the singular forms “a,” “an,” and “the” include plural referents unless the context clearly dictates otherwise. Thus, for example, reference to a “polymer” includes aspects having two or more such polymers unless the context clearly indicates otherwise.

Ranges can be expressed herein as from “about” one particular value and/or to “about” another particular value. When such a range is expressed, another aspect includes from the one particular value and/or to the other particular value. Similarly, when values are expressed as approximations, by use of the antecedent “about,” it will be understood that the particular value forms another aspect. It should be further understood that the endpoints of each of the ranges are significant both in relation to the other endpoint, and independently of the other endpoint.

As used herein, the terms “optional” or “optionally” mean that the subsequently described event or circumstance may or may not occur, and that the description includes instances where said event or circumstance occurs and instances where it does not.

For the terms “for example” and “such as,” and grammatical equivalences thereof, the phrase “and without limitation” is understood to follow unless explicitly stated otherwise.

The following patents, applications and publications as listed below and throughout this document are hereby incorporated by reference in their entirety herein.

### Reference list #1

[1] W. T. Chen, A. Y. Zhu, V. Sanjeev, M. Khorasaninejad, Z. Shi, E. Lee, F. Capasso, A broadband achromatic metalens for focusing and imaging in the visible, Nat. Nanotechnol. 13 (2018) 220-226.
[2] P. Moitra, B. A. Slovick, W. Li, I. I. Kravchencko, D. P. Briggs, S. Krishnamurthy, J. Valentine, Large-scale all-dielectric metamaterial perfect reflectors, Acs Photonics. 2 (2015) 692-698.
[3] W.-C. Wang, C.-W. Lin, H.-J. Chen, C.-W. Chang, J.-J. Huang, M.-J. Yang, B. Tjahjono, J.-J. Huang, W.-C. Hsu, M.-J. Chen, Surface passivation of efficient nanotextured black silicon solar cells using thermal atomic layer deposition, ACS Appl. Mater. Interfaces. 5 (2013) 9752-9759.
[4] S. V Sreenivasan, Nanoimprint lithography steppers for volume fabrication of leading-edge semiconductor integrated circuits, Microsystems Nanoeng. 3 (2017) 1-19.
[5] S. H. Ahn, S. Yang, M. Miller, M. Ganapathisubramanian, M. Menezes, J. H. Choi, F. Y. Xu, D. J. Resnick, S. V Sreenivasan, High-performance wire-grid polarizers using jet and Flash™ imprint lithography, J. Micro/Nanolithography, MEMS, MOEMS. 12 (2013) 31104.
[6] P. B. Catrysse, S. Fan, Nanopatterned metallic films for use as transparent conductive electrodes in optoelectronic devices, Nano Lett. 10 (2010) 2944-2949.
[7] J. Proust, F. Bedu, B. Gallas, I. Ozerov, N. Bonod, All-dielectric colored metasurfaces with silicon Mie resonators, ACS Nano. 10 (2016) 7761-7767.
[8] S. A. Boden, D. M. Bagnall, Optimization of moth-eye antireflection schemes for silicon solar cells, Prog. Photovoltaics Res. Appl. 18 (2010) 195-203.
[9] Y. M. Yeap, N. Geddada, A. Ukil, Capacitive discharge based transient analysis with fault detection methodology in dc system, Int. J. Electr. Power Energy Syst. 97 (2018) 127-137.
[10] H. Park, Y. Dan, K. Seo, Y. J. Yu, P. K. Duane, M. Wober, K. B. Crozier, Filter-free image sensor pixels comprising silicon nanowires with selective color absorption, Nano Lett. 14 (2014) 1804-1809.
[11] H. Na, T. Endoh, A Multi-Pillar Vertical Metal—Oxide—Semiconductor Field-Effect Transistor Type Dynamic Random Access Memory Core Circuit for Sub-1 V Core Voltage Operation without Overdrive Technique, Jpn. J. Appl. Phys. 52 (2013) 04CE08.
[12] B. Gawlik, C. Barrera, T. Y. Edward, S. V Sreenivasan, Hyperspectral imaging for high-throughput, spatially resolved spectroscopic scatterometry of silicon nanopillar arrays, Opt. Express. 28 (2020) 14209-14221.
[13] C. Raymond, Overview of scatterometry applications in high volume silicon manufacturing, in: AIP Conf. Proc., 2005: pp. 394-402.
[14] M. H. Madsen, P.-E. Hansen, Imaging scatterometry for flexible measurements of patterned areas, Opt. Express. 24 (2016) 1109-1117.
[15] B. M. Gawlik, G. Cossio, H. Kwon, Z. Jurado, B. Palacios, S. Singhal, A. Alù, T. Y. Edward, S. V Sreenivasan, Structural coloration with hourglass-shaped vertical silicon nanopillar arrays, Opt. Express. 26 (2018) 30952-30968.
[16] R. Sabbagh, B. Gawlik, S. V. Sreenivasan, A. Stothert, V. Majstorovic, D. Djurdjanovic, Big Data Curation for Analytics within the Cyber-Physical Manufacturing Metrology Model (CPM3), Procedia CIRP. (2020).
[17] M. G. Moharam, T. K. Gaylord, Rigorous coupled-wave analysis of planar-grating diffraction, JOSA. 71 (1981) 811-818.
[18] A. Taflove, S. C. Hagness, Computational electrodynamics: the finite-difference time-domain method, Artech house, 2005.
[19] “Lumerical.” https://www.lumerical.com/products/fdtd/.
[20] A. Bhattacharya, Fundamentals of database indexing and searching, CRC Press, 2014.
[21] T. Kohonen, Self-organizing map, Proc. IEEE. 78 (1990) 1464-1480.
[22] Sabbagh, R., Gawlik, B., Sreenivasan, S. V., Stothert, A., Majstorovic, V., & Djurdjanovic, D. (2020). Big data curation for analytics within the cyber-physical manufacturing metrology model (CPM3). Procedia CIRP, 93, 491-495
[23] Sabbagh, R., Živkovid, S., Gawlik, B., Sreenivasan, S. V., Stothert, A., Majstorovic, V. and Djurdjanovic, D., 2022. Organization of big metrology data within the Cyber-Physical Manufacturing Metrology Model (CPM3). CIRP Journal of Manufacturing Science and Technology, 36, pp.90-99.
[24] Sabbagh, R., Stothert, A., Sreenivasan, S. V., & Djurdjanovic, D. (2023). Optical Metrology of Critical Dimensions in Large-Area Nanostructure Arrays With Complex Patterns. Journal of Manufacturing Science and Engineering, 145(6), 061010.
[25]R. Ramakrishnan, J. Gehrke, Database management systems, McGraw Hill, 2000.
[26]J. Van De Groep, P. Spinelli, A. Polman, Transparent conducting silver nanowire networks, Nano Lett. 12 (2012) 3138-3144.
[27]K. Seo, M. Wober, P. Steinvurzel, E. Schonbrun, Y. Dan, T. Ellenbogen, K. B. Crozier, Multicolored vertical silicon nanowires, Nano Lett. 11 (2011) 1851-1856.
[28]Y.-F. Huang, S. Chattopadhyay, Y.-J. Jen, C.-Y. Peng, T.-A. Liu, Y.-K. Hsu, C.-L. Pan, H.-C. Lo, C.-H. Hsu, Y.-H. Chang, others, Improved broadband and quasi-omnidirectional anti-reflection properties with biomimetic silicon nanostructures, Nat. Nanotechnol. 2 (2007) 770-774.
[29]H. Chung, H. Kim, H. Kim, K. Kim, S. Kim, K.-W. Song, J. Kim, Y. C. Oh, Y. Hwang, H. Hong, others, Novel 4F 2 DRAM cell with vertical pillar transistor (VPT), in: 2011 Proc. Eur. Solid-State Device Res. Conf., 2011: pp. 211-214.
[30]Y. Sun, H. Y. Yu, N. Singh, E. Gnani, G. Baccarani, K. C. Leong, G. Q. Lo, D. L. Kwong, Junction-less stackable SONOS memory realized on vertical-Si-nanowire for 3-D application, in: 2011 3rd IEEE Int. Mem. Work., 2011: pp. 1-4.
[31]H. J. Park, T. Xu, J. Y. Lee, A. Ledbetter, L. J. Guo, Photonic color filters integrated with organic solar cells for energy harvesting, ACS Nano. 5 (2011) 7055-7060.
[32]L. Wen, Q. Chen, S. Song, Y. Yu, L. Jin, X. Hu, Photon harvesting, coloring and polarizing in photovoltaic cell integrated color filters: efficient energy routing strategies for power-saving displays, Nanotechnology. 26 (2015) 265203.
[33]J. Y. Lee, K.-T. Lee, S. Seo, L. J. Guo, Decorative power generating panels creating angle insensitive transmissive colors, Sci. Rep. 4 (2014) 1-6.
[34]A. Cao, E. J. R. Sudhölter, L. C. P. M. De Smet, Silicon nanowire-based devices for gas-phase sensing, Sensors. 14 (2014) 245-271.
[35]C. R. Field, H. J. In, N. J. Begue, P. E. Pehrsson, Vapor detection performance of vertically aligned, ordered arrays of silicon nanowires with a porous electrode, Anal. Chem. 83 (2011) 4724-4728.
[36]H. Zhao, Vertical silicon nanowire arrays for gas sensing, Massachusetts Institute of Technology, 2013.
[37]H. Park, K. B. Crozier, Vertically stacked photodetector devices containing silicon nanowires with engineered absorption spectra, Acs Photonics. 2 (2015) 544-549.
[38]W.-K. Kim, S. Lee, D. H. Lee, I. H. Park, J. S. Bae, T. W. Lee, J.-Y. Kim, J. H. Park, Y. C. Cho, C. R. Cho, others, Cu mesh for flexible transparent conductive electrodes, Sci. Rep. 5 (2015) 1-8.
[39]S. Chang, J. Oh, S. T. Boles, C. V Thompson, Fabrication of silicon nanopillar-based nanocapacitor arrays, Appl. Phys. Lett. 96 (2010) 153108.
[40]A. Cherala, M. Chopra, B. Yin, A. Mallavarapu, S. Singhal, O. Abed, R. Bonnecaze, S. V Sreenivasan, Nanoshape imprint lithography for fabrication of nanowire ultracapacitors, IEEE Trans. Nanotechnol. 15 (2016) 448-456.
[41]D. McMullan, Scanning electron microscopy 1928—1965, Scanning. 17 (1995) 175-185.
[42]L. Reimer, Scanning electron microscopy: physics of image formation and microanalysis, (2000).
[43]F. J. Giessibl, Advances in atomic force microscopy, Rev. Mod. Phys. 75 (2003) 949.
[44]D. Rugar, P. Hansma, Atomic force microscopy, Phys. Today. 43 (1990) 23-30.
[45]J. S. Villarrubia, A. E. Vladar, M. T. Postek Jr, Simulation study of repeatability and bias in the critical dimension scanning electron microscope, J. Micro/Nanolithography, MEMS, MOEMS. 4 (2005) 33002.
[46]M. S. S. Khan, L. H. Yang, X. Deng, S. F. Mao, Y. B. Zou, Y. G. Li, H. M. Li, Z. J. Ding, Critical-dimension scanning electron microscope characterization of smoothly varying wave structures with a Monte Carlo simulation, J. Phys. D. Appl. Phys. 54 (2021) 445301.
[47]K. Hitomi, Y. Nakayama, H. Yamanashi, Y. Sohda, H. Kawada, Study of measurement condition optimization in critical dimension-scanning electron microscope, Jpn. J. Appl. Phys. 47 (2008) 6554.
[48]M. Hayat, Basic techniques for transmission electron microscopy, Elsevier, 2012.
[49]B. Fultz, J. M. Howe, Transmission electron microscopy and diffractometry of materials, Springer Science & Business Media, 2012.
[50] No Title, (n.d.). https://nanocomposix.com/pages/nanoparticle-characterization-techniques #target.
[51]S. R. Spurgeon, C. Ophus, L. Jones, A. Petford-Long, S. V Kalinin, M. J. Olszta, R. E. Dunin-Borkowski, N. Salmon, K. Hattar, W.-C. D. Yang, others, Towards data-driven next-generation transmission electron microscopy, Nat. Mater. 20 (2021) 274-279.
[52]M. H. Madsen, P.-E. Hansen, Scatterometry-fast and robust measurements of nano-textured surfaces, Surf Topogr. Metrol. Prop. 4 (2016) 23003.
[53]J. J. Faria-Briceno, V. Sasidharan, A. Neumann, S. Singhal, S. V Sreenivasan, S. R. J. Brueck, High-speed in-line optical angular scatterometer for high-throughput roll-to-roll nanofabrication, in: Nov. Patterning Technol. 2021, 2021: p. 116100F.
[54]Y. Feng, J. Ervin, Y. Lu, A. Woo, M. Coogans, I. Chakarov, D. Fried, Scatterometry-based calibration of a 3D virtual fabrication model for gate-all-around devices, in: Des. Co-Optimization XV, 2021: p. 1161401.
[55]J. Lee, B. Bagheri, H.-A. Kao, A cyber-physical systems architecture for industry 4.0-based manufacturing systems, Manuf. Lett. 3 (2015) 18-23.
[56] Canon, n.d. https://www.j-platpat.inpit.go.jp/c1800/PU/JP-2021-002807/1A71A219352CB7D311DFA17D895B43C5E6097ABE6EC4B1F93950CD307A815C8 3/11/ja.
[57] Coherix, (n.d.). https://coherix.com/.
[58]B. Snyder, M. Yang, S. Singhal, O. Abed, S. V Sreenivasan, Automated tuning of high-order waveforms for picoliter resolution jetting of rheologically challenging materials, Precis. Eng. 56 (2019) 143-155.
[59]S. M. Stojadinovic, V. D. Majstorovic, N. M. Durakbasa, T. V Sibalija, Towards an intelligent approach for CMM inspection planning of prismatic parts, Measurement. 92 (2016) 326-339.
[60]V. Majstorovic, S. Stojadinovic, S. Zivkovic, D. Djurdjanovic, Z. Jakovljevic, N. Gligorijevic, Cyber-physical manufacturing metrology model (CPM3) for sculptured surfaces—turbine blade application, Procedia CIRP. 63 (2017) 658-663.
[61]V. Majstorovic, S. Zivkovic, D. Djurdjanovic, R. Sabbagh, V. Kvrgic, N. Gligorijevic, Building of Internet of Things Model for Cyber-Physical Manufacturing Metrology Model (CPM3), Procedia CIRP. (2019).
[62]R. U. Islam, M. S. Hossain, K. Andersson, A novel anomaly detection algorithm for sensor data under uncertainty, Soft Comput. 22 (2018) 1623-1639.
[63]G. A. Susto, M. Terzi, A. Beghi, Anomaly detection approaches for semiconductor manufacturing, Procedia Manuf 11 (2017) 2018-2024.
[64]L. Scime, J. Beuth, Anomaly detection and classification in a laser powder bed additive manufacturing process using a trained computer vision algorithm, Addit. Manuf. 19 (2018) 114-126.
[65]B. Fritzke, A growing neural gas network learns topologies, in: Adv. Neural Inf. Process. Syst., 1995: pp. 625-632.
[66]T. Martinetz, Competitive Hebbian learning rule forms perfectly topology preserving maps, in: Int. Conf. Artif Neural Networks, 1993: pp. 427-434.
[67]D. S. Hochbaum, D. B. Shmoys, A best possible heuristic for the k-center problem, Math. Oper. Res. 10 (1985) 180-184.
[68]R. Sabbagh, Z. Cai, A. Stothert, D. Djurdjanovic, Physically Inspired Data Compression and Management for Industrial Data Analytics, Front. Comput. Sci. 2 (2020) 41.
[69]B. Fritzke, Growing cell structures—a self-organizing network for unsupervised and supervised learning, Neural Networks. 7 (1994) 1441-1460.
[70]M. Buckland, F. Gey, The relationship between recall and precision, J. Am. Soc. Inf Sci. 45 (1994) 12-19.
[71]V. Majstorovic, S. Stojadinovic, S. Zivkovic, D. Djurdjanovic, Z. Jakovljevic, N. Gligorijevic, Cyber-physical manufacturing metrology model (CPM3) for sculptured surfaces—turbine blade application, Procedia CIRP. 63 (2017) 658-663.
[72]G. K. Wertheim, M. A. Butler, K. W. West, D. N. E. and Buchanan, Determination of the Gaussian and Lorentzian content of experimental line shapes, Rev. Sci. Instrum. 45 (1974) 1369-1371.
[73]S. V Sreenivasan, Nanoscale manufacturing enabled by imprint lithography, MRS Bull. 33 (2008) 854-863.
[74]M. Elsharkawy, T. M. Schutzius, C. M. Megaridis, Inkjet patterned superhydrophobic paper for open-air surface microfluidic devices, Lab Chip. 14 (2014) 1168-1175.
[75]Y. Noguchi, T. Sekitani, T. Yokota, T. Someya, Direct inkjet printing of silver electrodes on organic semiconductors for thin-film transistors with top contact geometry, Appl. Phys. Lett. 93 (2008) 273.
[76]T. Yasui, Y. Inoue, T. Naito, Y. Okamoto, N. Kaji, M. Tokeshi, Y. Baba, Inkjet injection of DNA droplets for microchannel array electrophoresis, Anal. Chem. 84 (2012) 9282-9286.
[77]B. Derby, Bioprinting: inkjet printing proteins and hybrid cell-containing materials and structures, J. Mater. Chem. 18 (2008) 5717-5721.
[78]R. Daly, T. S. Harrington, G. D. Martin, I. M. Hutchings, Inkjet printing for pharmaceutics—a review of research and manufacturing, Int. J. Pharm. 494 (2015) 554-567.
[79]M. Kyobula, A. Adedeji, M. R. Alexander, E. Saleh, R. Wildman, I. Ashcroft, P. R. Gellert, C. J. Roberts, 3D inkjet printing of tablets exploiting bespoke complex geometries for controlled and tuneable drug release, J. Control. Release. 261 (2017) 207-215.
[80]M. Versluis, High-speed imaging in fluids, Exp. Fluids. 54 (2013) 1-35.
[81]O. Demirkaya, M. H. Asyali, P. K. Sahoo, Image processing with MATLAB: applications in medicine and biology, CRC Press, 2008.
[82]C. Cortes, M. Mohri, A. Rastogi, On the computation of some standard distances between probabilistic automata, in: Int. Conf. Implement. Appl. Autom., 2006: pp. 137-149.
[83]A. Tarantola, Inverse problem theory and methods for model parameter estimation. SIAM, 2005.
[84]R. C. Aster, B. Borchers, and C. H. Thurber, Parameter estimation and inverse problems. Elsevier, 2018.
[85] Biros, G., Ghattas, O., Heinkenschloss, M., Keyes, D., Mallick, B., Tenorio, L., van Bloemen Waanders, B., Willcox, K., Marzouk, Y. and Biegler, L. eds., 2011. Large-scale inverse problems and quantification of uncertainty. John Wiley & Sons.
[86]T. Bui-Thanh, O. Ghattas, J. Martin, and G. Stadler, “A computational framework for infinite-dimensional Bayesian inverse problems Part I: The linearized case, with application to global seismic inversion,” SIAM J. Sci. Comput., vol. 35, no. 6, pp. A2494—A2523, 2013.
[87]N. Petra, J. Martin, G. Stadler, and O. Ghattas, “A computational framework for infinite-dimensional Bayesian inverse problems, Part II: Stochastic Newton MCMC with application to ice sheet flow inverse problems,” SIAM J. Sci. Comput., vol. 36, no. 4, pp. A1525—A1555, 2014.
[88]K. Judd, “Forecasting with imperfect models, dynamically constrained inverse problems, and gradient descent algorithms,” Phys. D Nonlinear Phenom., vol. 237, no. 2, pp. 216-232, 2008.
[89]W. C. Thacker, “Oceanographic inverse problems,” Phys. D Nonlinear Phenom., vol. 60, no. 1-4, pp. 16-37, 1992.
[90]M. Bertero, P. Boccacci, and C. De Mol, Introduction to inverse problems in imaging. CRC press, 2021.
[91]J. K. Seo and E. J. Woo, Nonlinear inverse problems in imaging. John Wiley & Sons, 2012.
[92] Karwowski, J., 2009, “Inverse Problems in Quantum Chemistry,” Int. J. Quantum Chem., 109(11), pp. 2456-2463.
[93] Li, X., Li, Z., and Wang, L., 2003, “The Inverse Problems for Some Topological Indices in Combinatorial Chemistry,” J. Comput. Biol., 10(1), pp. 47-55.
[94] Engl, H. W., Flamm, C., Kügler, P., Lu, J., Müller, S., and Schuster, P., 2009, “Inverse Problems in Systems Biology,” Inverse Probl., 25(12), p. 123014.
[95] Forss6n, P., Arnell, R., and Fornstedt, T., 2006, “An Improved Algorithm for Solving Inverse Problems in Liquid Chromatography,” Comput. Chem. Eng., 30(9), pp. 1381-1391.
[96] de Vito, E., Rosasco, L., Caponnetto, A., de Giovannini, U., Odone, F., and Bartlett, P., 2005, “Learning From Examples as an Inverse Problem,” J. Mach. Learn. Res., 6(5), pp. 883-904.
[97] Prato, M., and Zanni, L., 2008, “Inverse Problems in Machine Learning: An Application to Brain Activity Interpretation,” J. Phys. Conf Ser., 135(1), p. 12085.
[98] Mohamad-Djafari, A., 2013, Inverse Problems in Vision and 3D Tomography, John Wiley & Sons, Hoboken, NJ.
[99] Jones, A. G., and Taylor, C. J., 1994, “Solving Inverse Problems in Computer Vision by Scale Space Reconstruction, MVA,” pp. 401-404.
[100] Zaoui, A., Menana, H., Feliachi, M., and Berthiau, G., 2010, “Inverse Problem in Nondestructive Testing Using Arrayed Eddy Current Sensors,” Sensors, 10(9), pp. 8696-8704.
[101]D. Fleisch, A student's guide to Maxwell's equations, Cambridge University Press, 2008.
[102] Liu, K.-Y., Liu, J., and Herbert, J. M., 2017, “Accuracy of Finite-Difference Harmonic Frequencies in Density Functional Theory,” J. Comput. Chem., 38(19), pp. 1678-1684.
[103] Pardo, D., Matuszyk, P. J., Puzyrev, V., Torres-Verdin, C., Nam, M. J., and Calo, V. M., 2021, Modeling of Resistivity and Acoustic Borehole Logging Measurements Using Finite Element Methods, Amsterdam, The Netherlands.
[104] More, J. J., and Sorensen, D. C., 1982, “Newton's Method.”
[105] Dennis, J. E., Jr., and More, J. J., 1977, “Quasi-Newton Methods, Motivation and Theory,” SIAM Rev., 19(1), pp. 46-89.
[106] Greiner, R., 1996, “PALO: A Probabilistic Hill-Climbing Algorithm,” Artif Intell., 84(1-2), pp. 177-208.
[107] Broyden, C. G., 1969, “A New Double-Rank Minimisation Algorithm. Preliminary Report,” Notices of the American Mathematical Society, Providence, RI, Vol. 16, No. 4. p. 670.
[108] Fletcher, R., 1970, “A New Approach to Variable Metric Algorithms,” Comput J., 13(3), pp. 317-322.
[109] Goldfarb, D., 1970, “A Family of Variable-Metric Methods Derived by Variational Means,” Math Comput., 24(109), pp. 23-26.
[110] Shanno, D. F., 1970, “Conditioning of Quasi-Newton Methods for Function Minimization,” Math Comput., 24(111), pp. 647-656.
[111] Saltelli, A., 2002, “Sensitivity Analysis for Importance Assessment,” Risk Anal., 22(3), pp. 579-590.
[112] Guyon, I., and Elisseeff, A., 2003, “An Introduction to Variable and Feature Selection,” J. Mach. Learn. Res., 3, pp. 1157-1182.
[113] Cunningham, P., Kathirgamanathan, B., and Delany, S. J., 2021, “Feature Selection Tutorial With Python Examples,” ArXiv Preprint ArXiv:2106.06437.
[114] Ronaghan, S., 2018, “The Mathematics of Decision Trees, Random Forest and Feature Importance in Scikit-learn and Spark, Towards Data Science,” https://towardsdatascience.com/the-mathematics-of-decision-trees-random-forest-and-feature-importance-in-scikit-learn-and-spark-f2861df67e3, Accessed Jan. 8, 2022.
[115] Woodbury, M. A., 1950, Inverting Modified Matrices, Department of Statistics, Princeton, NJ.
[116] Wolfe, P., 1969, “Convergence Conditions for Ascent Methods,” SIAM Rev., 11(2), pp. 226-235.
[117] Zanobini, A., Sereni, B., Catelani, M., and Ciani, L., 2016, “Repeatability and Reproducibility Techniques for the Analysis of Measurement Systems,” Measurement, 86, pp. 125-132.
[118] Postek, M. T., and Vladir, A. E., 2013, “Does Your SEM Really Tell the Truth?-How Would You Know?Part 1, Scanning, 35(6), pp. 355-361.
[119] Schneider, C. A., Rasband, W. S., and Eliceiri, K. W., 2012, “NIH Image to ImageJ: 25 Years of Image Analysis,” Nat. Methods., 9(7), pp. 671-675.
[120] Lam, A., 2020, “BFGS in a Nutshell: An Introduction to Quasi-Newton Methods, Towards Data Science,” https://towardsdatascience.com/bfgs-in-a-nutshell-an-introduction-to-quasi-newton-methods-21b0e13ee504, Accessed Jan. 9, 2022.
[121] Jimenez, D., Saenz, J. J., Iniguez, B., Sune, J., Marsal, L. F., and Pallares, J., 2004, “Modeling of Nanoscale Gate-All-Around MOSFETs,” IEEE Electron Dev. Lett., 25(5), pp. 314-316.
[122] Faria-Briceno, J. J., Zhu, R., Sasidharan, V., Neumann, A., Singhal, S., Sreenivasan, S. V. and Brueck, S. R. J., 2019. Optical angular scatterometry: In-line metrology approach for roll-to-roll and nanoimprint fabrication. Journal of Vacuum Science & Technology B, Nanotechnology and Microelectronics: Materials, Processing, Measurement, and Phenomena, 37(5), p.052904.
[123]G. Ongie, A. Jalal, C. A. Metzler, R. G. Baraniuk, A. G. Dimakis, and R. Willett, “Deep learning techniques for inverse problems in imaging,” IEEE J. Sel. Areas Inf. Theory, vol. 1, no. 1, pp. 39-56, 2020.
[124]A. Mohammad-Djafari, “Regularization, Bayesian inference, and machine learning methods for inverse problems,” Entropy, vol. 23, no. 12, p. 1673, 2021.
[125]L. Pilozzi, F. A. Farrelly, G. Marcucci, and C. Conti, “Machine learning inverse problem for topological photonics,” Commun. Phys., vol. 1, no. 1, p. 57, 2018.
[126]B. Sridharan, M. Goel, and U. D. Priyakumar, “Modern machine learning for tackling inverse problems in chemistry: molecular design to realization,” Chem. Commun., vol. 58, no. 35, pp. 5316-5331, 2022.
[127]M. H. Shahnas, D. A. Yuen, and R. N. Pysklywec, “Inverse problems in geodynamics using machine learning algorithms,” J. Geophys. Res. Solid Earth, vol. 123, no. 1, pp. 296-310, 2018.
[128] Liu, S., Chen, X., Yang, T., Guo, C., Zhang, J., Ma, J., Chen, C., Wang, C., Zhang, C. and Liu, S., 2022. Machine learning aided solution to the inverse problem in optical scatterometry. Measurement, 191, p.110811.
[129] Loh, W. L. (1996). On Latin hypercube sampling. The annals of statistics, 24(5), 2058-2080.
[130]L. Chrisman, “Latin Hypercube vs. Monte Carlo Sampling,” Analytica, 2014. [Online]. Available: https://analytica.com/latin-hypercube-vs-monte-carlo-sampling/#:~:text=The most compelling advantage of,developing and debugging a model.
[131]T. Chen and C. Guestrin, “Xgboost: A scalable tree boosting system,” in Proceedings of the 22nd acm sigkdd international conference on knowledge discovery and data mining, 2016, pp. 785-794.
[132] Aymane Hachcham, “XGBoost: Everything You Need to Know,” 2023. [Online]. Available: https://neptune.ai/blog/xgboost-everything-you-need-to-know
[133] XGBoost Documentation, “XGBoost Parameters,” 2022. [Online]. Available: https://xgboost.readthedocs.io/en/stable/parameter.html.
[134]E. Luellen, “Mastering XGBoost,” Towards Data Science, 2021. [Online]. Available: https://towardsdatascience.com/mastering-xgboost-2eb6bce6bc76 #:~:text=Arguably %2C there are six (6,maximum tree depth (a regularization.
[135] Scikit-learn developers (BSD License), “RandomizedSearchCV.” [Online]. Available: https://scikit-learn.org/stable/modules/generated/sklearn.model_selection.RandomizedSearchCV.html.
[136]B. Venkatesh and J. Anuradha, “A review of feature selection and its methods,” Cybern. Inf. Technol., vol. 19, no. 1, pp. 3-26, 2019.
[137] Recursive Feature Elimination Documentation, “RFE,” 2023. [Online]. Available: https://scikit-learn.org/stable/modules/generated/sklearn.feature_selection.RFE.html.
[138] Cornellius Yudha Wijaya. (2021). 5 Feature Selection Method from Scikit-Learn you should know. Towards Data Science. Retrieved from https://towardsdatascience.com/5-feature-selection-method-from-scikit-learn-you-should-know-ed4d116e4172.
[139] Malinowski, E. R. (1989). Statistical f—tests for abstract factor analysis and target testing. Journal of Chemometrics, 3(1), 49-60.
[140] Ram Seshadri, “Featurewiz,” 2020. [Online]. Available: https://pypi.org/project/featurewiz/.
[141]G. Biau and E. Scornet, “A random forest guided tour,” Test, vol. 25, no. 2, pp. 197-227, 2016.
[142]K. K. Nicodemus, J. D. Malley, C. Strobl, and A. Ziegler, “The behaviour of random forest permutation-based variable importance measures under predictor correlation,” BMC Bioinformatics, vol. 11, pp. 1-13, 2010.
[143]E. Winter, “The shapley value,” Handb. game theory with Econ. Appl., vol. 3, pp. 2025-2054, 2002.
[144]D. Jimenez, J. J. Saenz, B. Iniguez, J. Sune, L. F. Marsal, and J. Pallares, “Modeling of nanoscale gate-all-around MOSFETs,” IEEE Electron device Lett., vol. 25, no. 5, pp. 314-316, 2004.
[145] Nerissa Draeger, No Title, (2020). https://blog.lamresearch.com/finfets-give-way-to-gate-all-around/.
[146]“Semulator3D.” [Online]. Available: https://www.coventor.com/products/semulator3d/
[147]Y.-T. Wu, F. Ding, M.-H. Chiang, J. F. Chen, and T.-J. K. Liu, “Simulation-Based Study of Low Minimum Operating Voltage SRAM With Inserted-Oxide FinFETs and Gate-All-Around Transistors,” IEEE Trans. Electron Devices, vol. 69, no. 4, pp. 1823-1829, 2022.
[148] Feng, Y., Ervin, J., Lu, Y., Woo, A., Coogans, M., Chakarov, I. and Fried, D., 2021, February. Scatterometry-based calibration of a 3D virtual fabrication model for gate-all-around devices. In Design-Process-Technology Co-optimization XV (Vol. 11614, pp. 73-81). SPIE.
[149]J. Wang, “Machine-Learning Assisted Scatterometry Metrology on Nanosheet Transistors,” MS Thesis (advised by D. Djurdjanovic), Cockrell School of Engineering, The University of Texas at Austin, 2024.
[150] Chu, C.-L., Hsu, S. H., Chang, W. Y., et al. (2023). Stacked SiGe nanosheets p-FET for Sub-3 nm logic applications. Scientific Reports, 13, 9433. https://doi.org/10.1038/s41598-023-36614-2
[151] Chu, C.-L., et al. (2018). Stacked Ge-Nanosheet GAAFETs Fabricated by Ge/Si Multilayer Epitaxy. IEEE Electron Device Letters, 39(8), 1133-1136.
[152] Sun, X., Wang, D., Qian, L., Liu, T., Yang, J., Chen, K., Wang, L., Huang, Z., Xu, M., Wang, C., . . . (2023). A Novel Si Nanosheet Channel Release Process for the Fabrication of Gate-All-Around Transistors and Its Mechanism Investigation. Nanomaterials, 13, 504. https://doi.org/10.1109/LED.2018.2850366
[153] Lee, K.-S., Shin, W. C., Yeon, J.-W., Park, J.-Y. (2023). Impact of device-to-device interference in nanosheet field-effect transistors. Microelectronics Reliability, 145, 114995. http://doi.org/10.1016/j.microrel.2023.114995
[154] Valasa, S., Tayal, S., Thoutam, L. R., Ajayan, J., Bhattacharya, S. (2022). A critical review on performance, reliability, and fabrication challenges in nanosheet FET for future analog/digital IC applications. Micro and Nanostructures, 170, 207374. ISSN 2773-0123

What is claimed is:

1. A method for optical inspection of a processed semiconductor wafer or microelectromechanical device comprising:
obtaining or receiving a measured reflectance spectra profile for one or more processed semiconductor wafer or microelectromechanical devices acquired by a metrology equipment, including a processed semiconductor wafer or microelectromechanical device;
determining, via an analysis operation using one or more trained machine learning models, using the measured reflectance spectra profile, one or more critical dimension values associated with a periodic structure in at least one area, including a first area, of the processed semiconductor wafer or microelectromechanical device, wherein the one or more critical dimension values is determined by providing the measured reflectance spectra profile to the one or more trained machine learning models,
wherein the machine learning model was trained from a set of simulation outputs, as a training data set, of a physic-based simulation model,
wherein the set of simulation outputs comprises (i) the periodic structure in the at least one area of the processed semiconductor wafer or microelectromechanical device configured with a first set of one or more critical dimension values, (ii) the periodic structure in the at least one area of the processed semiconductor wafer or microelectromechanical device configured with a second set of one or more critical dimension values, and (iii) simulated reflectance spectra profiles for the periodic structures configured with the first set of one or more critical dimension values and the second set of one or more critical dimension values; and
outputting the determined one or more critical dimension values for the processed semiconductor wafer or microelectromechanical device, wherein the outputted one or more critical dimensional values, or a parameter derived therefrom, are used to accept or reject (i) the processed semiconductor wafer or microelectromechanical device, (ii) a batch associated with the processed semiconductor wafer or microelectromechanical device, or (iii) equipment or process employed in the fabrication of the processed semiconductor wafer or microelectromechanical device.

2. The method of claim 1, wherein the outputted one or more critical dimensional values, or a parameter derived therefrom, is used to accept or reject the processed wafer or the processed semiconductor wafer or microelectromechanical device and in real-time or off-line analysis.

3. The method of claim 1 or 2, wherein the periodic structure in the at least one area of the processed semiconductor wafer or microelectromechanical device includes at least one of: a repeating metal grating structure, a repeating metal grid structure, a repeating nanopillar structure, a repeating nanowire structure, vertical pillar transistor structure, a repeating planer structure, a repeating FinFET structure, and repeating gate-all-around (GAA) structure, or a Large-area Nanostructure Array (LNA).

4. The method of any one of claims 1-3, wherein the outputted one or more critical dimensional values, or a parameter derived therefrom, is used to trigger (i) a second measurement and analysis via the one or more trained machine learning models or (ii) a manual inspection of the processed semiconductor wafer or microelectromechanical device.

5. The method of any one of claims 1-4 further comprising:
determining, via the one or more trained machine learning models, a second set of one or more critical dimension values associated with a periodic structure in a second area of the processed semiconductor wafer or microelectromechanical device, wherein the determined second set of one or more critical dimension values, or a parameter derived therefrom, is used to accept or reject (i) the processed semiconductor wafer or microelectromechanical device, (ii) the batch associated with the processed semiconductor wafer or microelectromechanical device, or (iii) the equipment or process employed in the fabrication of the processed semiconductor wafer or microelectromechanical device.

6. The method of any one of claims 1-5 further comprising:
measuring the processed semiconductor wafer or microelectromechanical device to acquire the measured reflectance spectra profile; and
storing (i) the measured reflectance spectra profile and (ii) associated location or periodic structure of the processed semiconductor wafer or microelectromechanical device to provide for the analysis operation.

7. The method of any one of claims 1-6, wherein the one or more processed semiconductor wafer or microelectromechanical devices include a second processed semiconductor wafer or microelectromechanical device, the method includes
determining, via the one or more trained machine learning models, a third set of one or more critical dimension values associated with a periodic structure in an area of the second processed semiconductor wafer or microelectromechanical device, wherein the determined third set of one or more critical dimension values, or a parameter derived therefrom, is used to accept or reject (i) the second processed semiconductor wafer or microelectromechanical device, (ii) the batch associated with the processed semiconductor wafer or microelectromechanical device, or (iii) the equipment or process employed in the fabrication of the processed semiconductor wafer or microelectromechanical device.

8. The method of any one of claims 1-7 further comprising:
estimating, via a second trained machine learning model, using the measured reflectance spectra profile, the periodic structure in the at least one area of the processed semiconductor wafer or microelectromechanical device, and the estimated periodic structure is used to select the one or more trained machine learning models for the analysis operation.

9. The method of any one of claims 1-8, wherein the measured reflectance spectra profile is measured by Scatterometry-based metrology system as the metrology equipment.

10. The method of any one of claims 1-9, wherein the measured reflectance spectra profile corresponds to a measurement for a single location on a single processed semiconductor wafer or microelectromechanical device.

11. The method of any one of claims 1-10, wherein the measured reflectance spectra profile corresponds to a measurement for multiple locations on a single processed semiconductor wafer or microelectromechanical device from a metrology equipment having an arrayed sensor.

12. The method of claim 11, wherein the measured reflectance spectra profile is represented as an image having a plurality of pixels, wherein each pixel corresponds to an area of the processed semiconductor wafer or microelectromechanical device having a plurality of periodic structures.

13. The method of any one of claims 1-12, wherein the analysis operation is performed in a batch.

14. The method of any one of claims 1-12, wherein measurement by the metrology equipment is performed in a batch.

15. The method of any one of claims 1-14, wherein the processed semiconductor wafer or microelectromechanical device has an area greater than 300 mm².

16. The method of any one of claims 1-15, wherein the at least one area of the processed semiconductor wafer or microelectromechanical device has an area greater than 1 mm².

17. The method of any one of claims 1-16, wherein the one or more trained machine learning models includes XG-Boost.

18. The method of any one of claims 1-17, wherein the simulation tool includes a photonic multiphysics simulation tool.

19. The method of any one of claims 1-18, wherein the processed semiconductor wafer or microelectromechanical device is a silicon wafer, a glass sheet, or flexible roll-to-roll web, having a micropatterned or nanopatterned periodic structure.

20. The method of any one of claims 1-19, wherein the outputted one or more critical dimensional values, or a parameter derived therefrom, has comparable Gage R&R ratio to manual inspection operation via Scanning Electron Microscopy or Atomic Force Microscopy (AFM)-based metrology.

21. The method of any one of claims 1-20, wherein the processed semiconductor wafer or microelectromechanical device is configured as a dynamic random access memory (DRAM) core circuit, a static random access memory (SRAM) core circuit, a magnetoresistive random-access memory (MRAM) core circuit.

22. The method of any one of claims 1-20, wherein the processed semiconductor wafer or microelectromechanical device is configured as a photovoltaic device or cell.

23. The method of any one of claims 1-20, wherein the processed semiconductor wafer or microelectromechanical device is configured as a photovoltaic device or cell.

23. The method of any one of claims 1-20, wherein the processed semiconductor wafer or microelectromechanical device is configured as a microstructure devices, liquid crystal display (LCD), organic light emitting diode (OLED) display, or capacitive touch screen sensor.

24. The method of any one of claims 1-23, wherein the periodic structure in at least one area of the processed semiconductor wafer or microelectromechanical device is different from the first and second set of one or more critical dimension values, and wherein the analysis operation is not a matching operation.

25. A method of training a machine learning comprising:
generating, via a physic-based simulation model, a library of a plurality of simulation reflectance spectra profiles for a set of periodic structures in a semiconductor wafer or microelectromechanical device having an associated set of one or more critical dimension values,
wherein the generated library of the plurality of simulation reflectance spectra profiles and associated set of one or more critical dimension values are used to train a machine learning model, and wherein the trained machine learning model is subsequently used to determine one or more critical dimension values, or parameters derived therefrom, of a periodic structure in at least one area of the fabricated semiconductor wafer or microelectromechanical device from measured reflectance spectra profile acquired by a metrology equipment, wherein the determined one or more critical dimensional values, or the parameter derived therefrom, are used to accept or reject (i) the fabricated semiconductor wafer or microelectromechanical device, (ii) a batch associated with the fabricated semiconductor wafer or microelectromechanical device, or (iii) equipment or process employed in the fabrication of the fabricated semiconductor wafer or microelectromechanical device.

26. The method of claim 25 further comprising:
training the machine learning model using the plurality of simulation reflectance spectra profiles and the associated set of one or more critical dimension values.

27. The method of claim 25 or 26, wherein the library is generated using Latin Hypercube Sampling.

28. The method of any one of claims 25-27 further comprising:
down-selecting set of one or more critical dimension values for the library of the plurality of simulation reflectance spectra profiles to be used for the training.

29. A scatterometry-based metrology system comprising:
a test platform coupled to a laser source;
laser control system configured to perform scatterometry-based metrology on a work product in the test platform; and
an analysis system configured to perform optical inspection of critical dimensions of a processed wafer or work product using any one of the methods of claims 1-24.

30. An analysis system for scatterometry-based metrology comprising:
a processor; and
a memory having instructions stored thereon, wherein execution of the instructions by the processor cause the processor to perform optical inspection of critical dimensions of a processed semiconductor wafer or microelectromechanical device according to any one of the methods of claims 1-24.

31. A non-transitory computer readable medium having instructions stored thereon, wherein execution of the instructions by a processor causes the processor to perform optical inspection of critical dimensions of a processed semiconductor wafer or microelectromechanical device according to any one of the methods of claims 1-24.
